(19) United States
(12) Patent Application Publication
(10) Pub. No.: US 2026/0213110 A1
(43) Pub. Date: Jul. 23, 2026

(54) SILICON CARBIDE BASED TRIODE ELECTRON EMITTER AND PRODUCING AN ELECTRON BEAM WITH SAME

(71) Applicant: Government of the United States of America, as represented by the Secretary of Commerce, Gaithersburg, MD (US)

(72) Inventors: Henri Joseph Lezec, Silver Spring, MD (US); Dhruv Fomra, Gaithersburg, MD (US)

(21) Appl. No.: 19/449,551

(22) Filed: Jan. 15, 2026

Related U.S. Application Data
(60) Provisional application No. 63/748,058, filed on Jan. 22, 2025.

(51) Int. Cl. H01J 1/304; H01J 9/02; H01J 37/073

(52) U.S. Cl. CPC H01J 1/3044; H01J 9/025; H01J 37/073; H01J 2201/30484

(57) ABSTRACT

A silicon carbide based triode electron emitter includes a silicon carbide substrate having a top surface, an emitter tip formed integrally with and extending upward from the top surface of the silicon carbide substrate, an insulator layer on the top surface of the silicon carbide substrate and the emitter tip, and an extractor electrode with an extraction aperture. A lower surface of the extractor electrode is closer to an apex of the emitter tip than the top surface of the silicon carbide substrate. This emitter operates at a lower operating voltage, higher current density, and extended lifetime compared to conventional cold field emitters.

### CROSS-REFERENCE TO RELATED APPLICATION

This application claims the benefit of U.S. Provisional Patent Application Ser. No. 63/748,058 (filed Jan. 22, 2025), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BACKGROUND

The present invention generally relates to the field of electron emitters, and more particularly to techniques for generating electron beams using a silicon carbide based triode electron emitter.

Electron sources play a role in a wide range of technologies, from medical imaging and telecommunications to semiconductor manufacturing and scientific research. A key category of electron sources is cold field emitters, which rely on the quantum tunneling effect to extract electrons from a material's surface by applying a strong electric field. These emitters offer advantages such as high coherence, low energy spread, and potentially large brightness, making them attractive for applications like electron microscopy, lithography, and vacuum electronics. However, conventional cold field emitters often require high voltages for operation, posing challenges for device design and integration. Furthermore, their performance can degrade over time due to tip blunting and surface contamination.

Conventional cold field emitter technology often relies on sharp tips made of materials like tungsten or lanthanum hexaboride. These emitters typically require kilovolt biases for electron extraction, necessitating complex high-voltage electronics. While field emitter arrays (FEAs), such as Spindt-type emitters, offer lower operating voltages, they suffer from limitations in current density and lifetime due to tip degradation or delamination. These limitations restrict the widespread adoption of FEAs in applications demanding high current and stable emission. Furthermore, the fabrication of FEAs can be complex and challenging, limiting their scalability and cost-effectiveness.

Another significant drawback of conventional cold field emitters is their sensitivity to surface contamination. Maintaining the ultra-high vacuum conditions necessary for optimal operation adds complexity and cost to many applications. Moreover, the susceptibility of these emitters to ion bombardment can lead to further performance degradation and reduced lifetime. These challenges hinder their utilization in environments where high vacuum is difficult to maintain or where ion bombardment is unavoidable.

It is therefore an objective of the present invention to provide a silicon carbide based triode electron emitter capable of operating at lower voltages, thereby overcoming the above-mentioned disadvantages of the prior art at least in part. Accordingly, a triode configuration cold field emitter based on silicon carbide would be advantageous and would be favorably received in the art.

### BRIEF DESCRIPTION

One aspect of the present invention relates to a silicon carbide based triode electron emitter. A silicon carbide based triode electron emitter is a device that emits electrons from a silicon carbide material, employing a three-electrode configuration for controlling the electron emission. It should be appreciated that one electrode of the three (anode) is effectively located at infinity, such that the silicon carbide based triode electron emitter has a cathode emitter tip and integrated extractor electrode in proximity.

It may be provided that the silicon carbide based triode electron emitter comprises a silicon carbide substrate having a top surface. Silicon carbide, a compound of silicon and carbon, offers a robust platform for electron emission due to its exceptional thermal and electrical properties. One advantage of this arrangement is the high thermal conductivity of silicon carbide, which enables efficient heat dissipation during device operation, thereby mitigating performance degradation caused by excessive heating.

It may be provided that the silicon carbide based triode electron emitter comprises an emitter tip formed integrally with and extending upward from the top surface of the silicon carbide substrate, the emitter tip having a radius of curvature less than 20 nanometers. This structure provides a sharp emission point, significantly enhancing the electric field at the apex of the tip and thus facilitating electron extraction at lower voltages. One advantage of an emitter tip radius of curvature less than 20 nanometers is a substantial reduction in the operating voltage required for field emission. This allows for simpler device design and integration while maintaining high emission current. The integral formation of the emitter tip with the substrate ensures robust mechanical stability, further enhancing device reliability and longevity.

It may be provided that the silicon carbide based triode electron emitter comprises an insulator layer on the top surface of the silicon carbide substrate and the emitter tip, the insulator layer having a predetermined thickness. An insulator layer plays a role in preventing electrical breakdown by providing electrical isolation between the extractor electrode and the substrate. One advantage of a predetermined thickness insulator is that it provides a balance between field enhancement and breakdown prevention. A thinner insulator layer enhances the electric field at the emitter tip, while a thicker layer improves breakdown voltage. The selection of an appropriate thickness enables optimization of device performance by maximizing emission current while mitigating breakdown risk.

It may be provided that the silicon carbide based triode electron emitter comprises an extractor electrode on the insulator layer, the extractor electrode comprising an extraction aperture centered over the emitter tip. This three-electrode configuration enables precise control of the electron emission by modulating the electric field at the emitter tip. A critical advantage of this arrangement is the low operating voltage enabled by the proximity of the extractor electrode to the emitter tip. This triode structure enhances the electric field at the tip, leading to substantial reductions in the required extraction voltage. The centered extraction aperture focuses the electric field, further enhancing emission efficiency and enabling precise control over the emitted electron beam. A further advantage of having the lower surface of the extractor electrode closer to the apex of the emitter tip than the top surface of the silicon carbide substrate is that it maximizes the field enhancement effect while maintaining sufficient dielectric strength to prevent breakdown. This ensures efficient electron emission at reduced operating voltages.

One aspect of the present invention relates to a process for fabricating a silicon carbide based triode electron emitter. It may be provided that the process for fabricating comprises providing a silicon carbide substrate having a top surface. Silicon carbide, with its exceptional material properties, offers a robust foundation for fabricating electron emitters. One advantage of silicon carbide is its high thermal conductivity, enabling efficient heat dissipation during device operation and thus improving device reliability and performance.

It may be provided that the process for fabricating comprises forming an emitter tip integrally with and extending upward from the top surface of the silicon carbide substrate, the emitter tip having a radius of curvature less than 20 nanometers. This nanometer-scale emitter tip provides a sharp emission point for enhanced field emission. One advantage of this arrangement is the ability to form the tip integrally with the substrate, which ensures mechanical robustness and stability, reducing the risk of tip breakage, delamination displacement during device operation or subsequent processing steps. The sharp tip radius enhances the electric field, enabling lower voltage operation.

It may be provided that the process for fabricating comprises depositing an insulator layer on the top surface of the silicon carbide substrate and the emitter tip, the insulator layer having a predetermined thickness. This insulator layer prevents electrical shorting between the extractor electrode and the substrate while allowing for a high electric field at the emitter tip. One advantage of this structure is the ability to tailor the insulator layer thickness. A thin insulator layer enhances field emission, while a thicker layer provides better electrical isolation. The predetermined thickness balances these factors for optimal device performance.

It may be provided that the process for fabricating comprises forming an extractor electrode on the insulator layer, the extractor electrode comprising an extraction aperture centered over the emitter tip. This extractor electrode, with its precisely positioned aperture, creates a strong, localized electric field at the emitter tip for efficient electron extraction. One advantage of the extractor aperture is its precise placement over the emitter tip. This focuses the electric field, maximizing emission efficiency. The arrangement where the lower surface of the extractor electrode is closer to the apex of the emitter tip than the top surface of the silicon carbide substrate enhances field emission and lowers the operating voltage. This arrangement also reduces the risk of arcing or breakdown between the electrode and substrate.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a cross-section of a single SiC electron emitter in an integrated triode configuration.

FIG. 2 shows, according to some embodiments, the electric field at the apex of a SiC emitter tip as a function of emitter tip radius.

FIG. 3 shows, according to some embodiments, steps in a fabrication process for a SiC triode electron emitter.

FIG. 4 shows, according to some embodiments, SEM images of SiC emitter tips fabricated using multi-pass (a) and single-pass (b) milling approaches.

FIG. 5 shows, according to some embodiments, SEM images of SiC emitter tips sharpened with (b) and without (a) XeF₂ gas.

FIG. 6 shows, according to some embodiments, a cross-sectional SEM image of a SiC emitter tip coated with LOR-3A resist and back-etched with O₂ plasma. The Pt layer is not part of the final device and is deposited as part of the preparation.

FIG. 7 shows, according to some embodiments, SEM images of a divot in a Ni film before (a) and after (b) circular aperture FIB milling.

### DETAILED DESCRIPTION

A detailed description of one or more embodiments is presented herein by way of exemplification and not limitation.

Conventional electron emitters, particularly cold field emitters, often suffer from limitations that hinder their broader application. Conventional technologies often require high operating voltages, limiting their use in portable or compact devices. Furthermore, the performance of these emitters tends to degrade over time due to factors like tip blunting and surface contamination, reducing their lifespan and reliability. Conventional fabrication techniques can also be complex and expensive, especially for field emitter arrays. These limitations have created a need for electron emitters with improved performance, lower operating voltages, and enhanced longevity.

The silicon carbide based triode electron emitter overcomes these limitations by employing a novel device architecture and fabrication process. It has been discovered that a silicon carbide based triode electron emitter, by incorporating a sharp emitter tip integrally formed with a silicon carbide substrate, can achieve efficient electron emission at significantly reduced voltages. One advantage of this emitter is its ability to operate at voltages below 100V, simplifying device design and integration compared to conventional emitters requiring kilovolt biases. The lower operating voltage also reduces the risk of electrical breakdown, enhancing device reliability and longevity.

Furthermore, the use of the refractory material silicon carbide as the substrate material offers additional advantages. Silicon carbide's high thermal conductivity enables efficient heat dissipation during device operation, mitigating performance degradation due to thermal effects. This enhances the emitter's stability and extends its operational lifetime compared to emitters fabricated from materials with lower thermal conductivity. The robust nature of silicon carbide also reduces susceptibility to tip blunting, further improving device longevity. One advantage of forming the emitter tip integrally with the substrate, as opposed to depositing an emission material on a substrate, is that it eliminates issues such as delamination or detachment of the emission material, which can occur in conventional field emitter array fabrication.

The incorporation of an insulator layer with a predetermined thickness provides a critical balance between field enhancement and electrical breakdown prevention. A thinner insulator enhances the electric field at the emitter tip, promoting electron emission at lower voltages. However, an excessively thin insulator increases the risk of electrical breakdown between the extractor electrode and the substrate. The predetermined thickness balances these competing factors, enabling low-voltage operation while preserving device reliability. A further advantage of having an extractor electrode on the insulator layer with an extraction aperture centered over the emitter tip is that it provides precise control of the emitted electron beam. This triode configuration significantly reduces the required extraction voltage compared to conventional emitters, by enhancing the electric field at the apex of the emitter tip. A further advantage of having the lower surface of the extractor electrode closer to the apex of the emitter tip than the top surface of the silicon carbide substrate is that it maximizes the field-enhancing effect of the extractor electrode while maintaining electrical isolation to prevent breakdown, which ensures both lower operating voltages and enhanced device longevity.

In an embodiment, a silicon carbide based triode electron emitter (10) comprises a silicon carbide substrate (12) having a top surface (14), an emitter tip (16) formed integrally with and extending upward from the top surface (14) of the silicon carbide substrate (12), the emitter tip (16) having a radius of curvature less than 20 nanometers, an insulator layer (18) disposed on the top surface (14) of the silicon carbide substrate (12) and the emitter tip (16), the insulator layer (18) having a predetermined thickness T, an extractor electrode (20) disposed on the insulator layer (18), the extractor electrode (20) comprising an extraction aperture (22) centered over the emitter tip (16); wherein a lower surface (24) of the extractor electrode (20) is closer to an apex (26) of the emitter tip (16) than the top surface (14) of the silicon carbide substrate (12). In an embodiment, the emitter tip (16) is conical. In an embodiment, the emitter tip (16) has a height H of at least 0.5 micrometers. In an embodiment, the insulator layer (18) has a thickness of less than 1 micrometer. In an embodiment, the insulator layer (18) is aluminum oxide. In an embodiment, the extractor electrode (20) is nickel. In an embodiment, the extraction aperture (22) is circular. In an embodiment, the extraction aperture (22) has a diameter from 100 nanometers to 500 nanometers. In an embodiment, the silicon carbide substrate (12) is n-type silicon carbide. In an embodiment, the silicon carbide substrate (12) has a thickness of at least 50 micrometers.

The silicon carbide based triode electron emitter (10) includes a silicon carbide substrate (12) having a top surface (14). The silicon carbide substrate (12) provides mechanical support and acts as the base material for the emitter. It can be a single-crystal wafer of high purity to ensure optimal electrical and thermal properties. The top surface (14) of the substrate (12) serves as the platform for subsequent fabrication steps. The silicon carbide substrate (12) may be doped to enhance electron conductivity and field emission. Alternatives to silicon carbide include other wide-bandgap semiconductors, such as aluminum nitride or gallium nitride, though their material properties may differ, impacting device performance. For example, in high-power applications, silicon carbide's superior thermal conductivity may be advantageous compared to aluminum nitride.

The emitter tip (16) is formed integrally with and extends upward from the top surface (14) of the silicon carbide substrate (12). The emitter tip (16) is the source of electrons in the field emission process. Its sharp radius of curvature, less than 20 nanometers, enhances the electric field at the apex, enabling electron emission at significantly lower voltages. The integral formation of the emitter tip (16) with the substrate (12) ensures mechanical robustness and prevents issues such as delamination or material mismatch that can occur with deposited emitter tips. The emitter tip (16) can be formed using focused ion beam milling, a precise technique capable of creating sharp, well-defined nanoscale structures. Alternative fabrication techniques include electron beam lithography or reactive ion etching, though their precision and control over tip geometry may differ compared to focused ion beam milling. For example, in applications where precise control over the emitter tip shape is required, focused ion beam milling may be preferred over other less precise techniques.

The insulator layer (18) is situated on the top surface (14) of the silicon carbide substrate (12) and the emitter tip (16), isolating the extractor electrode (20) from the substrate (12). The insulator layer's (18) predetermined thickness balances the need for field enhancement at the emitter tip (16) with the requirement for preventing electrical breakdown. A thin insulator enhances the electric field, but an excessively thin layer increases the risk of breakdown. The insulator layer (18) may be deposited using techniques such as sputtering or atomic layer deposition. The material can be a high dielectric strength material, like aluminum oxide or silicon dioxide. Alternative materials or deposition methods may alter the insulator's properties, such as its breakdown voltage or dielectric constant, impacting device performance. For example, for high-voltage applications, a material with a higher breakdown strength may be preferred.

The extractor electrode (20) resides on the insulator layer (18). It features an extraction aperture (22) centered over the emitter tip (16). The extractor electrode (20), typically made of a conductive metal such as nickel or chromium, creates a localized electric field for electron extraction. The extraction aperture (22), by being precisely centered over the emitter tip (16), focuses the electric field, ensuring efficient electron emission and beam formation. The configuration where the lower surface (24) of the extractor electrode (20) is closer to the apex (26) of the emitter tip (16) than the top surface (14) of the silicon carbide substrate (12) further enhances the electric field at the tip, reducing the required extraction voltage and minimizing the risk of breakdown. Alternative electrode materials or aperture shapes can be employed, though their influence on field emission and beam characteristics may differ. For example, a smaller aperture diameter enhances field strength but reduces emission current. In a particular application where high emission current is not involved, a smaller extraction aperture may be preferred to further reduce the required operating voltage.

The silicon carbide based triode electron emitter (10) achieves significant technical advantages through the specific implementation of each element. The use of silicon carbide as the substrate material leverages its high thermal conductivity for efficient heat dissipation. The integrally formed emitter tip with a nanometer-scale radius of curvature enables substantial reductions in operating voltage. The insulator layer with its predetermined thickness balances field enhancement and breakdown prevention. The extractor electrode with a centered aperture and strategically positioned lower surface enhances field emission and lowers operating voltage while reducing breakdown risks. These features combine to provide a cold field emitter with improved performance, reduced operating voltage, and extended lifetime.

The emitter tip (16) can be conical, further enhancing field emission by concentrating the electric field at the apex. This conical shape is readily achievable using focused ion beam milling. Alternative tip shapes, such as cylindrical, parabolic or pyramidal, are possible, although their field enhancement properties may differ. A conical tip is particularly advantageous for focusing the emitted electron beam. The emitter tip (16) can also have a height of at least 0.5 micrometers, which ensures sufficient field enhancement while providing mechanical stability. Shorter tips may be more prone to mechanical damage during fabrication or operation. Taller tips may enhance field emission but can increase the risk of arcing or breakdown. The specific height can be tailored based on the desired operating voltage and application requirements. The insulator layer (18) thickness can be less than 1 micrometer. This thin insulator layer enhances the electric field at the emitter tip, facilitating electron emission at lower voltages. The insulator layer (18) may be aluminum oxide deposited by sputtering. Other high dielectric strength materials, such as silicon dioxide or hafnium oxide, may be used depending on the application needs. The extractor electrode (20) can be nickel, a readily available, conductive, and readily patternable material suitable for electrode fabrication. Other conductive materials such as chromium or platinum may also be used, though their properties, such as work function or sputtering yield, may differ. The extraction aperture (22) can be circular, enabling precise centering over the emitter tip (16) using standard lithographic techniques. Alternative aperture shapes, such as elliptical or square, are possible, though alignment and field shaping characteristics may differ. A circular aperture is particularly advantageous for producing a symmetric electron beam. The extraction aperture (22) can have a diameter from 100 nanometers to 500 nanometers. This range provides a balance between field enhancement and total emission current. Smaller apertures concentrate the field more effectively but limit the emission area. Larger apertures increase total current but may require higher operating voltages. The silicon carbide substrate (12) may be n-type silicon carbide, a material with enhanced electron conductivity. The choice of doping type and level can be optimized based on the desired electron emission characteristics. The silicon carbide substrate (12) can also have a thickness of at least 50 micrometers, which provides robust mechanical support and handling. Thinner substrates can be more fragile and challenging to process.

The silicon carbide based triode electron emitter (10) with its conical emitter tip (16) and height, thin insulator layer (18), nickel extractor electrode (20) with a circular aperture (22) of specified diameter, and n-type silicon carbide substrate (12) having a thickness greater than 50 micrometers offers a robust, efficient electron source. The conical tip shape and optimized height enhance field emission, while the thin insulator layer and tailored extractor electrode further reduce operating voltage and minimize breakdown risks. The use of n-type silicon carbide as the substrate leverages its high thermal conductivity and electron mobility. The circular aperture enables precise alignment and field shaping. These features combine to provide an electron emitter with improved performance, reduced operating voltage, and extended lifetime.

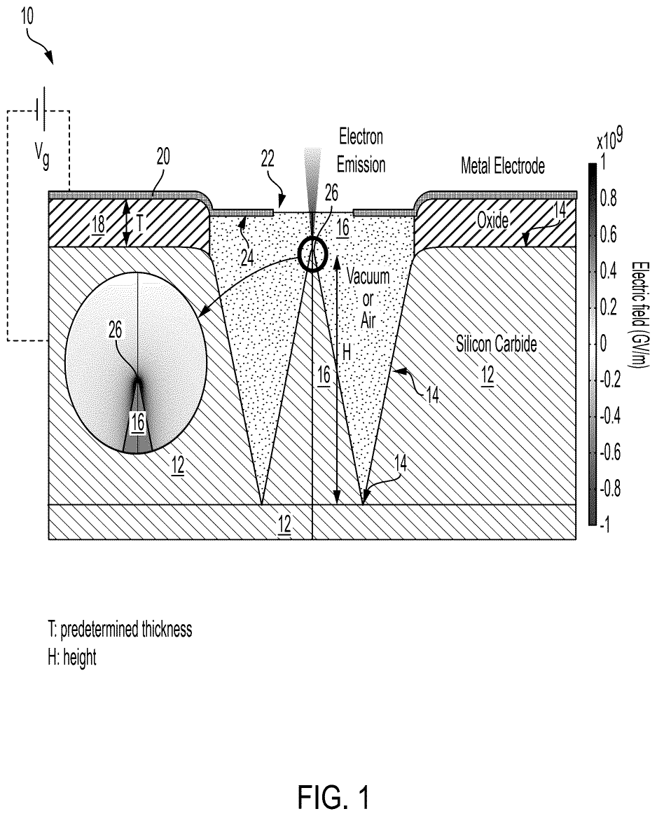

Silicon carbide based triode electron emitter 10 can be made of various elements and components that are microfabricated and can be various sizes. The silicon carbide based triode electron emitter 10 can include components that independently can have a size from 1 micrometer (μm) to 1 meter (m), specifically from 1 millimeter (mm) to 50 centimeters (cm), and more specifically from 1 mm to 10 cm. Elements of silicon carbide based triode electron emitter 10 can be made of a material that is physically or chemically resilient in an environment in which silicon carbide based triode electron emitter 10 is disposed. Exemplary materials include a metal, ceramic, thermoplastic, glass, semiconductor, and the like. The elements of silicon carbide based triode electron emitter 10 can be made of the same or different material and can be monolithic in a single physical body and can include additional elements that can be separate members that are physically joined or arranged on elements shown in FIG. 1.

The silicon carbide based triode electron emitter (10) distinguishes itself from conventional cold field emitters through its unique combination of material properties, device architecture, and fabrication methods. The silicon carbide based triode electron emitter (10) integrates a sharp emitter tip (16) formed from silicon carbide, a thin insulator layer (18), and an extractor electrode (20) with an extraction aperture (22) to achieve efficient electron emission at reduced operating voltages. The monolithic construction, with the emitter tip (16) integrally formed with the silicon carbide substrate (12), ensures mechanical robustness. This integrated structure eliminates potential failure mechanisms such as delamination or material mismatch often encountered in conventional field emitter arrays. The triode configuration, comprising the substrate (12), insulator layer (18), and extractor electrode (20), offers precise control over the emitted electron beam, enhancing its suitability for various applications such as electron microscopy and lithography. The device's (10) fabrication process employs focused ion beam milling for precise control over the emitter tip's (16) shape and radius of curvature, achieving nanometer-scale precision. The insulator layer (18) deposition can be accomplished using techniques like sputtering or atomic layer deposition, providing control over thickness and uniformity. The extractor electrode (20), with its precisely aligned aperture (22), can be fabricated using lithographic patterning and metal deposition methods. These fabrication methods enable precise control over the device geometry at the nanoscale, ensuring optimal field emission characteristics. Variations in material properties, device dimensions, and fabrication processes allow for customization of the emitter performance, broadening its applicability. For example, the doping concentration and type of the silicon carbide substrate (12) can be tailored to modify the electron emission characteristics. The thickness of the insulator layer (18) can be adjusted to balance field enhancement and breakdown voltage. The material and geometry of the extractor electrode (20), including the shape and size of the aperture (22), can be modified to control the emitted electron beam current and spot size. The silicon carbide based triode electron emitter (10) achieves enhanced performance and reliability through its unique structural and material properties. The use of silicon carbide as the base material (12) offers high thermal conductivity and mechanical robustness. The integral formation of the sharp emitter tip (16) ensures mechanical stability and enhances field emission at lower voltages. The thin insulator layer (18) and precisely positioned extractor electrode (20) with its aperture (22) further improve electron extraction efficiency and device lifetime. These design choices contribute to an electron emitter with reduced operating voltage, enhanced stability, and extended operational life.

The silicon carbide substrate (12) forms the foundation of the triode electron emitter (10). Its top surface (14) is the base for the emitter tip (16) and the subsequent layers. Choosing silicon carbide as the substrate material leverages its unique electrical and thermal properties. Silicon carbide's high thermal conductivity enables efficient heat dissipation, which maintains stable operation at high current densities. The high melting point and structural resistance to heat of the refractory material SiC contributes to stable operation at high current densities, over exceptionally long durations. Its wide bandgap contributes to high breakdown voltage and aids in device reliability. The substrate (12) can be doped, typically n-type, to enhance conductivity and improve field emission characteristics. The substrate (12) thickness, which can greater than 50 micrometers, provides mechanical robustness for handling and processing. While silicon carbide is a useful material for its superior properties, alternative substrate materials such as aluminum nitride or gallium nitride may be considered. However, these alternatives may exhibit lower thermal conductivity or breakdown voltage. For example, in high-power applications requiring efficient heat dissipation, silicon carbide could offer an advantage compared to aluminum nitride. The top surface (14) of the substrate (12) can be polished and cleaned to ensure optimal adhesion and uniformity of the subsequently deposited layers. The surface preparation may involve techniques like chemical mechanical polishing or reactive ion etching to achieve a smooth and contamination-free surface. Variations in surface roughness or the presence of contaminants can impact the performance and reliability of the device. The substrate (12) provides mechanical support for the emitter tip (16), insulator layer (18), and extractor electrode (20), ensuring the structural integrity of the silicon carbide based triode electron emitter (10). The substrate (12) also plays a role in electrical operation by providing a conductive path for the emitted electrons. Its material properties, such as its doping concentration and resistivity, can be tailored to optimize the device's electrical characteristics. For example, a highly doped substrate can reduce the series resistance and enhance the overall efficiency of the emitter. The silicon carbide substrate's (12) high thermal conductivity and wide bandgap contribute to a robust, reliable platform for the emitter (10). The substrate's top surface (14), prepared for optimal adhesion and uniformity, ensures proper interface quality for subsequent layers. These properties enable stable device operation at high current densities and elevated temperatures, expanding the application space for cold field emitters.

The top surface (14) of the silicon carbide substrate (12) is useful for the fabrication and operation of the triode electron emitter (10). It serves as the foundation upon which the emitter tip (16) is formed and the insulator layer (18) is deposited. The surface (14) finish and cleanliness provide proper adhesion and uniformity of the subsequent layers. A smooth, contamination-free top surface (14) can be achieved through various preparation techniques such as chemical mechanical polishing or reactive ion etching. The surface roughness and the presence of any contaminants can influence the growth and morphology of the emitter tip (16) and the uniformity of the insulator layer (18). Variations in the surface preparation methods can result in different surface characteristics, affecting the device performance. For example, a rougher top surface (14) might lead to non-uniform growth of the emitter tip (16) or variations in the thickness of the insulator layer (18), which can affect field emission and device reliability. The top surface (14) also plays a role in the device's thermal performance. Silicon carbide's high thermal conductivity allows efficient heat dissipation from the emitter tip (16) through the substrate (12). The quality of the interface between the top surface (14) and the subsequently deposited layers influences the thermal transport, affecting the device's ability to handle high current densities.

The emitter tip (16) serves as the source of electrons. It is formed integrally with and extends upward from the top surface (14) of the silicon carbide substrate (12), ensuring a robust mechanical and electrical connection. The emitter tip (16) terminates in a sharp radius of curvature, e.g., less than 20 nanometers, which significantly enhances the electric field at the apex (26). This field enhancement enables electron emission at significantly lower voltages compared to conventional cold field emitters, simplifying device design and integration by reducing the need for complex high-voltage electronics. The emitter tip (16) can be formed using focused ion beam (FIB) milling, a technique capable of producing nanoscale structures with high precision. A single-pass FIB milling strategy that includes a single, inward spiraling mill path covering a ring shaped area can create a conical tip shape, further optimizing field emission by concentrating the electric field at the apex. To further sharpen the tip and achieve a radius of curvature below 20 nanometers, a gas-assisted FIB milling process using XeF₂ can be employed. This gas-assisted etching process selectively etches the silicon carbide, resulting in an even sharper tip. Alternative fabrication methods for forming the emitter tip (16) include electron beam lithography or reactive ion etching although FIB milling offers superior control over tip geometry at the nanoscale. The height of the emitter tip (16), e.g., in the micrometer range, provides sufficient field enhancement while maintaining mechanical stability. Variations in the tip height can be used to optimize the device for specific operating conditions or application requirements. For example, a taller tip may enhance field emission but could also increase the risk of electrical breakdown. The emitter tip (16) material, being silicon carbide, inherits the material's excellent thermal and electrical properties. This allows efficient heat dissipation during device operation, preventing performance degradation due to thermal effects and prolonging device lifetime. The integral formation of the emitter tip (16) with the silicon carbide substrate (12) avoids material mismatch or delamination issues, ensuring a robust and reliable electron source.

The insulator layer (18) provides electrical isolation between the extractor electrode (20) and the silicon carbide substrate (12). It is deposited on the top surface (14) of the substrate (12) and the emitter tip (16), ensuring complete electrical separation. The insulator layer's (18) predetermined thickness plays a role in determining the device's performance and reliability. A thinner insulator layer enhances the electric field at the emitter tip (16) for a given applied voltage, promoting field emission. However, a very thin insulator layer increases the risk of electrical breakdown between the extractor electrode (20) and the substrate (12). The predetermined thickness is chosen to balance these competing effects, enabling electron emission at lower voltages while ensuring device reliability. Exemplary insulator layer (18) materials include aluminum oxide, silicon dioxide, or other high dielectric strength materials. Aluminum oxide is often preferred for its high breakdown voltage and ease of deposition. The insulator layer (18) can be deposited using techniques like sputtering, atomic layer deposition, or chemical vapor deposition. Sputtering is a commonly used method for depositing thin films with control over thickness and uniformity. Variations in the insulator layer material and deposition methods can influence its electrical and mechanical properties, which, in turn, can affect device performance. For instance, the dielectric constant of the insulator material affects the electric field strength at the emitter tip, which subsequently influences the field emission current. Similarly, the insulator's mechanical properties, such as its stress and adhesion to the substrate, can affect the device's long-term stability and reliability.

The predetermined thickness of the insulator layer (18) is a parameter in achieving efficient field emission and preventing electrical breakdown. This thickness is selected to balance two competing requirements. First, a thinner insulator layer enhances the electric field at the emitter tip (16) for a given applied voltage, thereby increasing the field emission current. Second, the insulator layer must be sufficiently thick to prevent electrical breakdown between the extractor electrode (20) and the silicon carbide substrate (12). The specific predetermined thickness will depend on the material properties of the insulator layer (18), the desired operating voltage, and the geometry of the emitter (10). A thickness less than 1 micrometer can enhance field emission while maintaining sufficient breakdown voltage, especially when using high dielectric strength materials such as aluminum oxide. For example, a 200 nm thick aluminum oxide layer can withstand voltages up to 50V, which is sufficient for electron extraction while minimizing the risk of breakdown. Those skilled in the art will recognize that a variety of insulator layer materials and thicknesses are possible depending on the specific emitter design and operating conditions.

The extractor electrode (20), in part, creates the electric field for extracting electrons from the emitter tip (16). It is disposed on top of the insulator layer (18), ensuring electrical isolation from the silicon carbide substrate (12). The extractor electrode (20) can be made of a conductive material such as nickel, chromium, or other suitable metals. These materials are chosen for their high conductivity, ease of patterning, and compatibility with the fabrication process. The extractor electrode (20) incorporates an extraction aperture (22) precisely centered over the emitter tip (16). The aperture's (22) shape and size are parameters influencing the field emission characteristics. A circular aperture is useful for its symmetry and ease of fabrication using standard lithographic techniques. The aperture diameter, typically in the range of hundreds of nanometers, is selected to balance the electric field strength and the total emission current. A smaller aperture concentrates the electric field, enhancing emission at lower voltages, but can limit the total current. A larger aperture increases the current but may involve higher operating voltages. An aspect of the extractor electrode (20) design is the positioning of its lower surface (24) relative to the emitter tip's (16) apex (26) and the top surface (14) of the silicon carbide substrate (12). The lower surface (24) of the extractor electrode (20) is closer to the apex (26) of the emitter tip (16) than the top surface (14) of the substrate. This specific configuration maximizes the electric field enhancement at the tip's apex (26) while maintaining sufficient electrical isolation between the extractor electrode (20) and the substrate (12) provided by the insulator layer (18), enabling efficient electron emission at reduced operating voltages and minimizing the risk of electrical breakdown. Variations in extractor electrode (20) design, such as using different materials, aperture shapes, or relative positioning, are possible. For example, the extractor electrode (20) can be made of different metals with varying work functions. The extraction aperture (22) can be elliptical, rectangular, or other shapes, which can influence the emitted beam profile. The distance between the lower surface (24) of the extractor electrode (20) and the emitter tip (16) apex (26) can be further optimized to fine-tune the device performance.

The extraction aperture (22) is a feature of the extractor electrode (20) that can focus the electric field at the emitter tip (16), maximizing the efficiency of electron extraction and shaping the emitted electron beam. The extraction aperture (22) is bounded by the central portion of the extractor electrode (20) and is precisely centered over the emitter tip (16). This alignment concentrates the electric field at the apex (26) of the emitter tip (16) and provides optimal field emission. The aperture (22) can be circular, which simplifies fabrication using conventional lithographic techniques and facilitates precise alignment with the emitter tip (16). The aperture's (22) diameter, e.g., in the range of hundreds of nanometers, is a parameter that influences the emitter's (10) performance. A smaller diameter aperture concentrates the electric field more effectively, enhancing field emission but can limit the total emission current. A larger diameter aperture increases the emission current but can reduce the field enhancement at the emitter tip (16) and may involve higher operating voltages. The size of the extraction aperture (22) can be selected to balance these trade-offs depending on the specific application requirements. Variations in the extraction aperture's (22) shape and size can be explored to achieve particular electron beam profiles and current densities. While a circular aperture can be used, other shapes such as elliptical or rectangular apertures can produce different beam shapes. For instance, an elliptical aperture can generate an elliptical electron beam, which might be beneficial for specific applications.

The lower surface (24) of the extractor electrode (20) plays a role in the performance of the silicon carbide based triode electron emitter (10). Its strategic positioning relative to the emitter tip (16) and the silicon carbide substrate (12) enhances field emission and reduces the operating voltage. The lower surface (24) of the extractor electrode (20) faces the emitter tip (16) and is positioned closer to the apex (26) of the emitter tip (16) than the top surface (14) of the silicon carbide substrate (12). This arrangement maximizes the electric field enhancement at the apex (26) of the emitter tip (16), which is the point of highest field concentration. The increased field strength at the apex (26) facilitates electron tunneling and enables efficient field emission at reduced operating voltages. The closer proximity of the lower surface (24) to the emitter tip (16) compared to the substrate (12) also minimizes the distance electrons must travel to reach the extraction aperture (22). This configuration reduces the transit time and increases the emission current. Variations in the distance between the lower surface (24) and the emitter tip (16) can be used to optimize the device performance. For example, reducing this distance further can enhance field emission and care is taken to avoid electrical breakdown between the extractor electrode (20) and the emitter tip (16).

The apex (26) of the emitter tip (16) is the point of highest electric field concentration and a primary location of electron emission in the silicon carbide based triode electron emitter (10). Its sharp radius of curvature, inherited from the emitter tip (16) (e.g., less than 20 nanometers), amplifies the electric field applied between the extractor electrode (20) and the silicon carbide substrate (12), and it is this amplified electric field at the apex (26) that provides field emission. The apex's (26) position at the tip (16) of the emitter, extending upward from the substrate's (12) top surface (14), places it in close proximity to the extraction aperture (22) in the extractor electrode (20), further enhancing the field emission process. The apex's (26) sharpness is paramount for achieving low-voltage operation. A sharper apex amplifies the electric field more effectively, allowing for greater electron emission at reduced voltages. The composition of the apex (26), being silicon carbide, benefits from the material's high thermal conductivity, aiding in heat dissipation during operation and thus contributing to enhanced device stability and lifetime. While the apex (26) is inherently defined by the shape and geometry of the emitter tip (16), its characteristics are for the emitter's (10) operation.

Further, additional metallic apertures can be formed above the extractor aperture, wherein each is spaced apart from the next by insulating layers, to provide additional functionality such as beam shaping, focusing, acceleration, or retardation.

While silicon carbide (12) is discussed above as a material for the substrate due to its exceptional thermal and electrical properties, alternative materials such as aluminum nitride (AlN) or gallium nitride (GaN) material can be considered. These materials offer different combinations of thermal conductivity, bandgap, and mechanical properties that may be advantageous for particular applications. For example, AlN offers high thermal conductivity comparable to silicon carbide, making it suitable for high-power applications. GaN, with its higher electron mobility, could enhance the emitter's frequency response. The choice of substrate material can influence the device design and fabrication process. For instance, the etching characteristics of different materials may necessitate different FIB milling parameters or gas chemistries. The insulator layer (18) can also be fabricated from a variety of dielectric materials beyond aluminum oxide. Silicon dioxide, hafnium oxide, or other high-k dielectrics can be considered. The choice of insulator material impacts the device's performance by influencing the electric field strength at the emitter tip (16). Higher dielectric constant materials enhance the field, but their breakdown voltage may differ. The deposition method for the insulator layer (18) can also be varied. In addition to sputtering, techniques like atomic layer deposition or chemical vapor deposition can be used to achieve precise control over the insulator thickness and uniformity, which can affect the field enhancement and breakdown characteristics. The extractor electrode (20) can be fabricated from various conductive materials. Metals like tungsten, molybdenum, or tantalum, known for their high melting points and stability at elevated temperatures, can be used, especially for high-power applications. The choice of extractor material can affect its work function, which influences the electron emission characteristics. The shape and size of the extraction aperture (22) can also be varied beyond a circular opening. Elliptical, rectangular, or other geometries can be implemented to control the shape and directionality of the emitted electron beam. The fabrication methods for creating the aperture can also vary. In addition to FIB milling, techniques like laser ablation or photolithography can be used depending on the desired precision and throughput. These variations in materials and fabrication methods provide flexibility in tailoring the emitter's performance for specific applications. For instance, materials with higher thermal conductivity and lower work functions can enhance field emission, while materials with higher breakdown strength improve device reliability and longevity.

The dimensions of the silicon carbide based triode electron emitter (10) and its components can be varied to optimize performance for specific applications. While the emitter tip (16) radius of curvature can be less than 20 nanometers to enhance field emission, the tip height can range from hundreds of nanometers to several micrometers. Taller tips can enhance the electric field, and it is contemplated that excessively tall tips can increase the risk of arcing or mechanical instability. The insulator layer (18) thickness can also be varied. While thicknesses below one micrometer can enhance field emission, thicker layers can provide improved electrical isolation and prevent breakdown at higher operating voltages. The thickness can be chosen based on the desired operating voltage and the dielectric strength of the insulator material. The extractor electrode (20) dimensions, including the extraction aperture (22) diameter, can be tailored to specific application needs. The aperture (22) diameter can range from tens of nanometers to several micrometers. Smaller apertures enhance field emission but may limit the total emission current. Larger apertures increase the current but can reduce the field enhancement effect and potentially increase the operating voltage. The thickness of the extractor electrode (20) can influence its mechanical stability and thermal properties. Thicker electrodes provide better heat dissipation, which can be beneficial for high-power applications. The overall size of the silicon carbide substrate (12) can range from millimeters to centimeters, depending on the application requirements and fabrication constraints. Larger substrates can accommodate multiple emitters (10) in an array configuration, enabling higher total emission currents. The substrate thickness, which can be, e.g., greater than 50 micrometers to provide mechanical robustness, can be adjusted based on handling and thermal management requirements. For example, thinner substrates may be preferred for applications where weight or thermal resistance can be a concern. These variations in device dimensions demonstrate the flexibility of the emitter design and its adaptability to a wide range of applications. The ability to tailor the dimensions of individual components, including the emitter tip (16), insulator layer (18), extractor electrode (20) including its aperture (22), and silicon carbide substrate (12), provides flexibility in optimizing the device performance for various applications such as electron microscopy, lithography, or vacuum electronics.

The shape and geometry of the silicon carbide based triode electron emitter (10) and its components can be varied to optimize performance and adapt the emitter to specific applications. While a conical shape for the emitter tip (16) is used for its field enhancement properties, alternative shapes such as cylindrical, parabolic, pyramidal, or even more complex geometries, like a blade or wedge shape, are possible. The choice of tip shape influences the electric field distribution and the resulting electron emission pattern. For example, a parabolic tip may offer advantages in terms of beam focusing, while a blade-shaped tip could produce a sheet-like electron beam. The insulator layer (18) can be conformal to the underlying surfaces and can have variations in its shape or profile depending on the deposition method and subsequent processing. For example, if the insulator layer is deposited using a directional technique like sputtering, its thickness may vary across the surface, creating a non-uniform profile. This non-uniformity could be advantageous in certain applications by influencing the electric field distribution. The extractor electrode (20), can be planar or cupped (e.g., convex toward the emitter tip) with a circular extraction aperture (22) to focus the electric field, can also be designed with different shapes and topographies. A non-planar extractor electrode (20), for example, one with a curved or tapered surface, could be used to further shape or direct the emitted electron beam. The extraction aperture's (22) shape can also be varied beyond a simple circular opening. Elliptical, rectangular, or more complex aperture (22) geometries can be employed to generate electron beams with specific profiles. The shape and size of the extraction aperture (22), coupled with the extractor electrode's (20) overall shape, can be used to tailor the electron beam characteristics for specific applications, like shaping the electron beam spot size or divergence angle for lithography or microscopy. These variations in device geometry, while not altering the basic functionality of the emitter (10), offer flexibility in tailoring its performance and beam characteristics for specific applications, expanding the emitter's utility beyond the limitations of conventional cold field emitters.

In an embodiment, a process for fabricating a silicon carbide based triode electron emitter (10) comprises: providing a silicon carbide substrate (12) having a top surface (14), forming an emitter tip (16) integrally with and extending upward from the top surface (14) of the silicon carbide substrate (12), the emitter tip (16) having a radius of curvature less than 20 nanometers, depositing an insulator layer (18) on the top surface (14) of the silicon carbide substrate (12) and the emitter tip (16), the insulator layer (18) having a predetermined thickness, and forming an extractor electrode (20) on the insulator layer (18), the extractor electrode (20) comprising an extraction aperture (22) centered over the emitter tip (16), wherein a lower surface (24) of the extractor electrode (20) is closer to an apex (26) of the emitter tip (16) than the top surface (14) of the silicon carbide substrate (12). In an embodiment, forming the emitter tip (16) comprises focused ion beam milling. In an embodiment, the focused ion beam milling comprises a single-pass milling strategy. In an embodiment, the emitter tip (16) is formed to have a conical shape. In an embodiment, the process further comprises sharpening the emitter tip (16) using focused ion beam milling in the presence of XeF₂ gas. In an embodiment, depositing the insulator layer (18) comprises sputtering. In an embodiment, the insulator layer (18) is aluminum oxide. In an embodiment, forming the extractor electrode (20) comprises sputtering, the extractor electrode (20) comprising nickel. In an embodiment, the extraction aperture (22) is formed using focused ion beam milling. In an embodiment, the process further comprises planarizing the substrate (12) and the emitter tip (16) using layers of photoresist, and back-etching the photoresist using oxygen plasma to create a recess over each emitter tip (16).

The process for fabricating a silicon carbide based triode electron emitter (10) addresses the challenges of creating sharp, nanoscale emitter tips and integrating them with precise control over the device geometry. The process can begin by providing a silicon carbide substrate (12) having a top surface (14), which serves as the foundation for the emitter. Silicon carbide's high thermal conductivity and electrical properties are advantageous for field emission devices. The substrate (12) can be a single-crystal wafer that undergoes cleaning and surface preparation to ensure optimal conditions for subsequent fabrication steps. Next, an emitter tip (16) is formed integrally with and extending upward from the top surface (14) of the substrate (12). The emitter tip (16), with its radius of curvature less than 20 nanometers, is the electron source, its sharpness enhancing the electric field and thus enabling electron emission at lower voltages. This integral formation ensures a robust mechanical and electrical connection between the tip (16) and the substrate (12), which improves device stability and reliability. Focused ion beam (FIB) milling, a technique capable of creating nanoscale features with high precision, can be used to form the emitter tip (16). A subsequent step involves depositing an insulator layer (18) on the top surface (14) of the substrate (12) and the emitter tip (16). The insulator layer (18), with its predetermined thickness, is useful for electrically isolating the extractor electrode (20) from the substrate (12). The thickness is chosen to balance field emission enhancement at the emitter tip (16) with breakdown prevention between the extractor (20) and the substrate (12). Sputtering, a technique for depositing thin films with good control over thickness and uniformity, can be employed. The process concludes by forming an extractor electrode (20) on the insulator layer (18). The extractor electrode (20) incorporates an extraction aperture (22) centered over the emitter tip (16). This electrode creates a localized electric field for electron extraction, and the aperture (22) focuses the field onto the emitter tip (16). The lower surface (24) of the extractor electrode (20) is closer to the apex (26) of the emitter tip (16) than the top surface (14) of the substrate (12), further enhancing field emission at lower voltages and minimizing breakdown. The extractor electrode (20) can be made from materials like nickel or chromium using techniques such as sputtering or evaporation, followed by lithographic patterning and etching to define the aperture (22).

The fabrication process, starting with a silicon carbide substrate (12) with a prepared top surface (14), forms an integral emitter tip (16) with a nanoscale radius for enhanced, lower voltage field emission. The insulator layer (18), having a predetermined thickness, is deposited to provide electrical isolation, preventing breakdown while enhancing field emission. The extractor electrode (20) is formed with a centered extraction aperture (22), creating a strong localized electric field at the emitter tip (16) for efficient electron extraction. The closer proximity of the extractor electrode's (20) lower surface (24) to the emitter tip's (16) apex (26) maximizes field enhancement while maintaining breakdown prevention. These process steps result in a silicon carbide based triode electron emitter (10) with improved performance, reduced operating voltage, and extended lifetime.

The step of forming the emitter tip (16) can use focused ion beam (FIB) milling, a technique well-suited for creating nanoscale structures with high precision. FIB milling uses a focused beam ions such as gallium ions to sputter material from a surface, enabling precise control over the shape and dimensions of the emitter tip (16). The milling parameters, such as beam current, dwell time, and scan pattern, can be adjusted to create tips with varying heights, apex angles, and radii of curvature. A single-pass milling strategy in which a beam of appropriate current and diameter is scanned in a single, outside to inside, circular or spiral pattern over a ring shaped area, naturally yields a conical tip profile (16). Such a milling strategy minimizes material redeposition on the emitter tip and gallium contamination of the tip (16), factors that can degrade field emission performance. The resulting conical shape of the emitter tip (16) concentrates the electric field at the apex (26) and enables low-voltage operation. Other ions available as a high-current focused beam, such as nitrogen, oxygen, argon or xenon, can be used instead of gallium to form conical tips, to avoid gallium contamination or to decrease milling time to form a tip. The process can also include a step of sharpening the emitter tip (16) using focused ion beam milling in the presence of XeF₂ gas. This gas-assisted etching process improves tip sharpness, reducing the radius of curvature to less than 20 nanometers, further enhancing field emission efficiency and lowering the operating voltage. The insulator layer (18) can be deposited using a sputtering process, enabling precise thickness control. Sputtering involves bombarding a target material with energetic ions, causing atoms to be ejected and deposited onto the substrate (12) and emitter tip (16), which forms a thin, uniform film. The insulator layer can be aluminum oxide (Al₂O₃), which exhibits a high dielectric strength, minimizing leakage current and preventing breakdown. The extractor electrode (20) can be formed by a sputtering process and comprise nickel, providing a highly conductive path for the extracted electrons. Nickel's electrical conductivity minimizes resistive losses, enhancing the efficiency of the emitter (10), and sputtering can create a thin, uniform electrode layer. The extraction aperture (22) can be formed using focused ion beam milling, enabling precise alignment and control over its shape and size. Precise alignment of the aperture (22) with the emitter tip (16) ensures that the electric field is focused for efficient electron extraction, maximizing emission current. The fabrication process can also include a planarization step using multiple layers of photoresist, followed by back-etching with oxygen plasma to create a recess over each emitter tip (16). This recess aids in aligning the extraction aperture (22) with the emitter tip (16) during subsequent processing and minimizes variations in the distance between the lower surface (24) of the extractor electrode (20) and the emitter tip's (16) apex (26), which can lead to more uniform emission characteristics across the emitter array. The use of focused ion beam milling, particularly a single-pass strategy, provides high precision in forming the emitter tip's conical shape, further enhanced by sharpening with XeF₂ gas. Sputtering the insulator layer (18), aluminum oxide, ensures controlled thickness and high dielectric strength. Forming the nickel extractor electrode (20) by sputtering guarantees high conductivity, and FIB milling the extraction aperture (22) provides precise alignment and dimensional control. Planarization and back-etching create a recess for aligning the extraction aperture (22) over the emitter tip (16), enhancing uniformity.

The fabrication of the silicon carbide based triode electron emitter (10) involves a series of precisely controlled steps to achieve the desired nanoscale features and device geometry. Starting with a silicon carbide substrate (12), the process begins with a thorough cleaning and surface preparation of the top surface (14). This can involve a combination of chemical cleaning and surface treatments to remove contaminants and ensure a smooth, uniform surface for subsequent processing. The formation of the emitter tip (16) is accomplished using focused ion beam (FIB) milling. A single-pass milling strategy minimizes gallium contamination and material redeposition. Precise control over the FIB milling parameters, including beam current, dwell time, and scan pattern, is useful for achieving the desired tip shape, height, and radius of curvature. Following FIB milling, a gas-assisted etching process using XeF₂ can further refine the emitter tip (16) shape and sharpness. This process enhances the tip's field emission properties by reducing its radius of curvature to less than 20 nanometers. The deposition of the insulator layer (18) is achieved using techniques like sputtering, atomic layer deposition, or chemical vapor deposition, chosen based on the desired insulator material, thickness, and uniformity requirements. Precise control over the deposition parameters is useful for achieving the desired insulator properties, influencing both the device's electrical performance and long-term reliability. The extractor electrode (20) is formed on the insulator layer (18) using standard thin film deposition techniques such as sputtering, evaporation, or chemical vapor deposition, followed by lithographic patterning and etching to create the extraction aperture (22). Precise alignment of the aperture (22) with the emitter tip (16) is for optimizing field emission. To enhance planarization and create a recess around the emitter tip (16), a layer of photoresist can be applied and patterned using standard lithography. The photoresist is then back-etched using an oxygen plasma to create a recessed area or divot, aiding in the alignment of the extraction aperture (22) during subsequent extractor electrode (20) fabrication and allowing precise control over the distance between the lower surface (24) of the extractor electrode (20) and the emitter tip's (16) apex (26). This recessed region enhances field emission by maximizing the field enhancement factor due to the closer proximity of the extractor to the emitter tip. After fabrication, the silicon carbide based triode electron emitter (10) is packaged in a vacuum environment, at pressures below 10⁻⁶ Torr, to minimize surface contamination and prevent electron scattering during operation. This vacuum environment is critical for maintaining stable and reliable field emission. To enable modulation of the emitted electron beam, the silicon carbide substrate (12) can be optically biased using a blue laser. The blue laser wavelength is chosen to coincide with the bandgap of silicon carbide, maximizing absorption and the effectiveness of the optical biasing, which enables high-speed modulation of the free electron population and work function at the tip surface and corresponding high-speed modulation of the emitted electron beam intensity, opening possibilities for applications like high-speed electron microscopy. The laser intensity and modulation frequency can be adjusted to control the electron beam modulation.

The process of fabricating the silicon carbide based triode electron emitter (10) commences with providing a silicon carbide substrate (12) having a top surface (14). The silicon carbide substrate (12) serves as the foundation for the emitter, providing mechanical support and electrical conductivity. Silicon carbide is a wide-bandgap semiconductor material known for its high thermal conductivity, excellent electrical properties, and mechanical robustness. These properties are advantageous for field emission devices, enabling efficient heat dissipation and high breakdown voltages. The substrate (12) can be a single-crystal wafer, which offers superior crystalline quality and uniformity compared to polycrystalline materials, minimizing defects and improving device performance and reliability. The top surface (14) of the substrate (12) is critical, as it acts as the interface for subsequent fabrication steps, influencing the growth of the emitter tip (16) and the deposition of the insulator layer (18). The top surface (14) can be subjected to a rigorous cleaning and preparation process to remove contaminants and ensure a smooth, uniform surface. This preparation may involve chemical cleaning, mechanical polishing, or a combination of techniques. The specific surface preparation method influences the surface roughness, which can affect the subsequent growth and morphology of the emitter tip (16). While silicon carbide is preferred due to its superior properties, alternative substrate materials such as aluminum nitride (AlN), gallium nitride (GaN), or diamond can be considered. These materials offer different combinations of thermal and electrical properties. For example, AlN has a thermal conductivity comparable to silicon carbide, while GaN offers higher electron mobility, which may be desirable for specific applications. The substrate's (12) size and thickness can also be varied depending on the application requirements. Larger substrates can accommodate multiple emitters in an array configuration, increasing total emission current. Thicker substrates provide better mechanical stability and handling, while thinner substrates may be preferred for applications with thermal management or weight constraints. The choice of substrate material and its preparation significantly influence the performance and reliability of the emitter.

Following the preparation of the silicon carbide substrate (12), a next step in fabricating the silicon carbide based triode electron emitter (10) can be forming the emitter tip (16). The emitter tip (16), integrally formed with and extending upward from the top surface (14) of the substrate (12), serves as the electron source. Its defining characteristic, a radius of curvature less than 20 nanometers, is for enhancing the electric field at the apex (26) and enabling field emission at reduced voltages. This sharp tip concentrates the electric field, facilitating electron tunneling and emission at significantly lower voltages compared to conventional cold field emitters. The emitter tip (16) can be formed using focused ion beam (FIB) milling, a technique capable of creating nanoscale structures with high precision and control. The FIB milling process can be optimized by employing a single-pass strategy, which minimizes material redeposition and gallium contamination, resulting in a sharper and cleaner emitter tip (16). Precise control over the FIB milling parameters, including beam current, dwell time, and scan pattern, enables precise control over the emitter tip's (16) final shape, height, and radius of curvature. These parameters can be adjusted to optimize the tip geometry for specific operating voltages or application requirements. While a conical shape is often preferred for its field enhancement properties, variations in tip shape, such as cylindrical, parabolic or pyramidal, are possible and may offer advantages in terms of beam focusing or other specialized emission patterns. The emitter tip's (16) height, typically on the order of micrometers, influences its mechanical stability and field enhancement factor. Taller tips can enhance field emission, but excessively tall tips may be more susceptible to mechanical damage or arcing. The emitter tip's (16) integral formation with the silicon carbide substrate (12) provides device reliability and performance. This monolithic structure eliminates potential issues such as delamination or material mismatch, which can occur in conventional field emitter arrays where the emitter tip is deposited on a separate substrate. Alternative methods for fabricating the emitter tip (16) include electron beam lithography and reactive ion etching. However, FIB milling offers advantages in terms of precision and control at the nanoscale, especially for creating sharp tips with well-defined geometries.

After forming the emitter tip (16), the next step in fabricating the silicon carbide based triode electron emitter (10) can be depositing the insulator layer (18). This layer is deposited on the top surface (14) of the silicon carbide substrate (12) and the emitter tip (16). It electrically isolates the extractor electrode (20) from the substrate (12), preventing electrical shorting and ensuring that the applied voltage generates the desired electric field at the emitter tip (16). The insulator layer's (18) predetermined thickness is a critical design parameter. A thinner insulator layer enhances the electric field at the emitter tip (16) for a given applied voltage, promoting field emission, but excessively thin insulator layers can lead to electrical breakdown between the extractor electrode (20) and the substrate (12). The predetermined thickness is selected to balance these competing requirements, optimizing electron emission while preserving device reliability. The insulator layer (18) can be deposited using sputtering, a process that offers excellent control over film thickness and uniformity. In sputtering, a target material is bombarded with energetic ions, causing atoms to be ejected from the target and deposited onto the substrate (12), forming a thin film. Alternative deposition methods, like atomic layer deposition or chemical vapor deposition, can be considered, particularly if precise control over thickness, composition, and conformality are paramount. The preferred material for the insulator layer (18) is aluminum oxide due to its high dielectric strength, which minimizes leakage current and reduces the risk of electrical breakdown. Other high dielectric constant materials, including silicon dioxide (SiO₂), hafnium oxide (HfO₂), or silicon nitride (Si₃N₄), are possible alternatives. However, material properties such as dielectric constant, bandgap, and breakdown voltage vary among these alternatives, and thus the specific choice of material influences the performance and reliability of the device.

The next step in fabricating the silicon carbide based triode electron emitter (10) can be forming the extractor electrode (20). This electrode is formed on top of the insulator layer (18) and plays a role in establishing the electric field necessary for electron extraction. The extractor electrode (20) can be fabricated from a conductive metal, such as nickel or chromium, chosen for its high electrical conductivity and compatibility with standard microfabrication techniques. These materials offer low resistivity, minimizing voltage drops and maximizing the efficiency of electron extraction. The extractor electrode (20) incorporates an extraction aperture (22) precisely centered over the emitter tip (16). This aperture (22), typically circular in shape, focuses the electric field generated by the applied voltage onto the emitter tip's (16) apex (26). The aperture's (22) diameter is a critical parameter affecting device performance; a smaller aperture concentrates the field more effectively but restricts the emission area, potentially reducing overall emission current. A larger aperture increases the current but may require higher voltages for efficient electron extraction. The extractor electrode (20) is strategically designed such that its lower surface (24) is closer to the apex (26) of the emitter tip (16) than the top surface (14) of the silicon carbide substrate (12). This unique configuration is achieved through the fabrication process and is involved in maximizing the field enhancement effect at the tip's apex (26) while preserving the electrical isolation provided by the insulator layer (18). This configuration enables efficient electron emission at significantly reduced operating voltages. The extractor electrode (20) can be formed using techniques such as sputtering, evaporation, or chemical vapor deposition, followed by lithographic patterning and etching to define the extraction aperture (22). Precise alignment of the aperture (22) with the emitter tip (16) is useful for maximizing field emission and shaping the emitted electron beam. Variations in extractor electrode design are possible, such as using alternative materials, aperture shapes, and configurations. For instance, materials like tungsten, molybdenum, or platinum, having high melting points and temperature stability, might be preferable for high-power or high-temperature applications. The extraction aperture (22) can be elliptical or rectangular rather than circular, allowing customization of the emitted electron beam profile. The spacing between the lower surface (24) of the extractor electrode (20) and the emitter tip's (16) apex (26) can also be varied to optimize device performance.

In an embodiment of the process for fabricating the silicon carbide based triode electron emitter (10), the step of forming the emitter tip (16) comprises focused ion beam (FIB) milling. This technique offers high precision and control for creating nanoscale structures, making it well-suited for fabricating the sharp emitter tip (16) necessary for efficient field emission. FIB milling employs a finely focused beam of gallium ions to sputter material from the silicon carbide substrate's (12) top surface (14), enabling precise shaping of the emitter tip (16). The parameters of the FIB milling process, such as beam current, dwell time, and scan pattern, can be meticulously controlled to achieve the desired tip geometry, including its height, apex angle, and radius of curvature. A single-pass milling strategy, wherein the ion beam scans the designated milling area only once, minimizes gallium implantation and material redeposition, which can negatively impact the emitter's performance. Variations in the FIB milling parameters can produce emitter tips (16) with different shapes and dimensions. For example, adjusting the beam current and dwell time influences the milling rate and the tip's final height. The scan pattern can be modified to create tips with varying apex angles and profiles. Gas-assisted FIB milling, using a reactive gas like XeF₂, can further enhance the milling process, achieving sharper tips by selectively etching the silicon carbide material. This gas-assisted process is particularly beneficial for achieving a radius of curvature below 20 nanometers, which maximizes the field enhancement at the emitter tip's apex (26) and thus promotes electron emission at lower voltages.

In a further embodiment of the process for fabricating the silicon carbide based triode electron emitter (10), the focused ion beam (FIB) milling employed for forming the emitter tip (16) comprises a single-pass milling strategy. This strategy distinguishes itself from conventional multi-pass FIB milling by minimizing material redeposition and gallium contamination, resulting in a sharper and cleaner emitter tip (16). In single-pass FIB milling, the focused ion beam scans the designated milling area only once. This minimizes the exposure of the emitter tip (16) to the gallium ion beam, reducing gallium implantation into the silicon carbide material. Gallium contamination can adversely affect the emitter's performance by altering the material's work function and increasing the voltage required for electron emission. The single-pass strategy also minimizes material redeposition. In multi-pass milling, sputtered material can redeposit on the emitter tip (16), creating a rougher surface and blunting the tip. This redeposition can negate the benefits of the FIB milling process, leading to a less sharp tip and higher operating voltages. By employing a single-pass strategy, the risk of material redeposition is significantly reduced, resulting in a cleaner, sharper tip and improved field emission characteristics. The single-pass milling strategy can be implemented using various scan patterns, like a spiral orcircular scan, typically from the outside perimeter to inside perimeter of a ring shaped area tailored to achieve specific tip shapes and minimize redeposition. The beam current and dwell time in single-pass milling should be carefully chosen to control the milling rate and prevent excessive material removal, which would otherwise shorten the emitter tip (16) or otherwise damage it. For example, a lower beam current with a faster scan speed might be preferred for minimizing gallium contamination, while higher beam current with a slower scan speed may be more efficient for removing larger amounts of material. It should be appreciated that FIB milling of the various materials in forming the silicon carbide based triode electron emitter 10 can be controlled and optimized by a machine learning algorithm to obtain precisely formed structures such as the aperture, tip shape, and other features.

In an embodiment of the fabrication process, the emitter tip (16) of the silicon carbide based triode electron emitter (10) is formed to have a conical shape. This conical geometry is advantageous for field emission as it concentrates the electric field at the apex (26) of the tip (16), thereby enhancing electron emission at lower voltages. The conical shape can be readily achieved using focused ion beam (FIB) milling, by controlling the milling parameters such as beam current, dwell time, and scan pattern. A single-pass milling strategy, as described previously, is particularly well-suited for creating conical emitter tips (16) with minimal gallium contamination and material redeposition. The conical shape's key advantage lies in its ability to concentrate the electric field lines at the apex (26), maximizing field enhancement. This field enhancement reduces the voltage required to achieve a given emission current, which simplifies device design and operation. The angle of the cone, a parameter readily controlled during the FIB milling process, influences the field enhancement factor. Steeper cone angles generally lead to higher field enhancement, but excessively steep angles may result in a mechanically fragile tip, increasing the risk of breakage during fabrication or operation. The conical shape also contributes to better heat dissipation from the apex of the emitter tip (16) by providing a larger surface area for thermal conduction to the silicon carbide substrate (12), mitigating performance degradation caused by thermal effects. While a conical shape is preferred for its field-enhancing properties, other tip shapes such as cylindrical, parabolic or pyramidal can be considered. These alternative shapes may offer different field emission characteristics, influencing the beam profile or angular distribution. For example, a parabolic tip might offer better beam focusing, whereas a pyramidal tip might produce a higher emission current.

A further refinement in the fabrication process for the silicon carbide based triode electron emitter (10) involves sharpening the emitter tip (16) using focused ion beam (FIB) milling in the presence of XeF₂ gas. This gas-assisted etching process selectively removes silicon carbide material, resulting in an even sharper emitter tip (16) with a radius of curvature that can be selected, e.g., to be less than 20 nanometers, for maximizing field emission at lower voltages. The XeF₂ gas enhances the FIB milling process by chemically reacting with the silicon carbide in the presence of the gallium ion beam, leading to enhanced material removal and a sharper tip. This chemical reaction is highly localized, confined to the area where the ion beam strikes the material, allowing for precise control over the sharpening process. The parameters of the gas-assisted FIB milling process, including the XeF₂ gas pressure, beam current, dwell time, and scan pattern, are carefully controlled to achieve the desired tip sharpness without introducing defects or damaging the emitter tip (16). Lower gas pressures and beam currents are typically employed during sharpening compared to the initial tip formation step to minimize material removal and achieve precise control over the tip shape. The XeF₂ gas-assisted FIB milling step builds upon the initially formed emitter tip (16), further refining its shape and reducing its radius of curvature to less than 20 nanometers. This sharpening process significantly enhances the electric field at the apex (26) of the tip, enabling electron emission at lower voltages compared to emitters with less sharp tips. Variations in the gas-assisted FIB milling parameters, such as using different gas pressures or beam currents, can yield tips with varying sharpness and shapes. Alternative sharpening techniques, such as oxidation followed by a wet etch, might be considered. Gas-assisted FIB milling offers advantages in terms of precision, control, and the ability to selectively etch the silicon carbide material, achieving a sharper tip without significantly altering the overall tip geometry.

In an embodiment of the fabrication process, depositing the insulator layer (18) on the silicon carbide based triode electron emitter (10) comprises sputtering. Sputtering offers excellent control over film thickness, uniformity, and composition, making it well-suited for creating a precise insulator layer (18) with the desired electrical properties. Sputtering involves bombarding a target material, having the same composition as the desired insulator layer, with energetic ions, typically argon. This bombardment ejects atoms from the target material, which then travel through a vacuum and deposit onto the substrate (12) and emitter tip (16), forming a thin, uniform insulator layer (18). The sputtering process parameters, such as the sputtering pressure, power, and substrate temperature, can be meticulously adjusted to achieve precise control over the insulator layer's (18) thickness, composition, and uniformity. The predetermined thickness of the insulator layer (18), typically in the range of hundreds of nanometers, is chosen to balance field enhancement at the emitter tip (16) with breakdown prevention. The sputtering process can be performed using various configurations such as DC sputtering, RF sputtering, or magnetron sputtering. DC sputtering is a simple and cost-effective technique often used for depositing conductive materials. RF sputtering is suitable for depositing both conductive and insulating materials due to its ability to generate a plasma even with non-conductive targets. Magnetron sputtering, by employing a magnetic field to confine the plasma near the target, enhances the deposition rate and reduces substrate heating, which can be advantageous for temperature-sensitive materials or devices. The specific choice of sputtering method will depend on the material being deposited and the desired film properties. For example, RF sputtering may be preferred for depositing aluminum oxide due to its insulating nature. Alternative techniques for depositing the insulator layer (18) include atomic layer deposition (ALD) and chemical vapor deposition (CVD). ALD offers exceptional control over thickness and uniformity, at the atomic level, producing highly conformal films, whereas CVD generally exhibits higher deposition rates and is more suitable for thicker films. However, sputtering is often preferred for its relative simplicity, cost-effectiveness, and good control over film thickness and uniformity, making it a versatile technique for a wide range of applications.

A further refinement in the fabrication process for the silicon carbide based triode electron emitter (10) involves planarizing the substrate (12) and the emitter tip (16) using multiple layers of photoresist, followed by a back-etching step using oxygen plasma to create a recess over each emitter tip (16). This planarization process improves the uniformity of the subsequently deposited insulator layer (18) and extractor electrode (20), which ensures consistent device performance. The multiple layers of photoresist are applied to the substrate (12) and emitter tip (16) using a spin-coating process. Spin coating creates a thin, uniform layer of photoresist by dispensing a liquid photoresist onto the rotating substrate. After each layer of photoresist is applied, it is baked to remove solvents and solidify the film. The thickness of each photoresist layer can be controlled by adjusting the spin speed and the viscosity of the photoresist. After depositing multiple photoresist layers and baking them, the photoresist is then back-etched using an oxygen plasma. Oxygen plasma etching is a dry etching technique that selectively removes the photoresist material. Due to electric field enhancement at the emitter tip (16), the etch rate is higher in the vicinity of the tip, resulting in a recess or divot forming over each emitter tip (16). The depth of the recess can be controlled by varying the oxygen plasma etch time and power. The planarization and back-etching steps create a more uniform surface topology, which improves the conformality and thickness uniformity of the subsequently deposited insulator layer (18) and extractor electrode (20). This is particularly important for achieving consistent device performance across an array of emitters. The recess formed over each emitter tip (16) also aids in aligning the extraction aperture (22) of the extractor electrode (20) with the emitter tip (16), which ensures the electric field is optimally focused for efficient field emission. While photoresist is commonly used for planarization, other materials like spin-on glass or polyimide can be employed. Similarly, alternative etching techniques, such as reactive ion etching with different gas chemistries, can be explored to achieve the desired recess depth and profile.

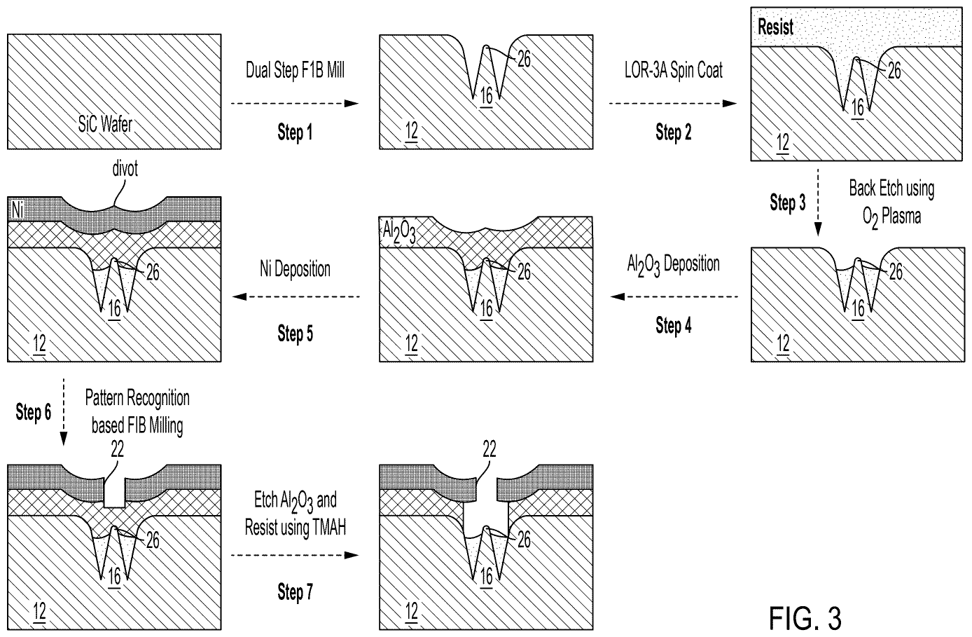

FIG. 3 details the fabrication process for the silicon carbide based triode electron emitter (10), outlining certain steps involved in creating the device's intricate structure. The process can begin with a silicon carbide wafer, typically a single-crystal wafer chosen for its superior material properties, which serves as the foundation for the emitter (10). A first step can involve a dual-step focused ion beam (FIB) mill to create the emitter tip (16). This step shapes the emitter tip (16) with a sharp apex (26) and precise geometry. This dual-step FIB milling process involves a high-current, single-pass milling step to create the initial tip shape, followed by a lower current, multi-pass milling step in the presence of XeF₂ gas for sharpening. The single-pass milling minimizes gallium contamination and material redeposition, creating a sharper tip. The XeF₂ gas-assisted milling further sharpens the tip to a radius of curvature less than 20 nanometers, which enhances field emission at lower voltages. The next step is the application of a LOR-3A spin coat. LOR is a spin-on photoresist commonly used in microfabrication for creating high-resolution patterns. Multiple layers of LOR-3A are spin-coated onto the substrate (12) and emitter tip (16) to planarize the surface and fill the gaps or trenches around the emitter tip (16). Each layer is baked after deposition to solidify the photoresist and improve planarization. The sample then undergoes a back-etching process using oxygen plasma. Oxygen plasma etching selectively removes the photoresist material. Due to the electric field enhancement at the emitter tip (16), the etching rate is locally higher, leading to a recess or divot forming over the emitter tip (16), which will aid in the subsequent alignment of the extractor electrode's (20) aperture (22). Following the LOR processing, aluminum oxide (Al₂O₃) is deposited, forming the insulator layer (18). Al₂O₃, a high dielectric strength material, is deposited using sputtering to a predetermined thickness, which can be less than 1 micrometer. The Al₂O₃ layer electrically isolates the extractor electrode (20) from the substrate (12) and the emitter tip (16), preventing electrical shorting and ensuring that the applied voltage between the extractor electrode (20) and the silicon carbide substrate (12) generates the required electric field at the apex (26) of the emitter tip (16) for field emission. Next, a nickel (Ni) layer is deposited, forming the extractor electrode (20). Nickel, a highly conductive material, is often chosen for the extractor electrode. The Ni layer is also deposited using sputtering and is patterned using photolithography and etching to create the extraction aperture (22), precisely centered over the emitter tip (16), which focuses the electric field for enhanced electron extraction and beam formation. After the nickel (Ni) layer is patterned, a pattern recognition-based focused ion beam milling process is used to mill circular apertures (22) through the nickel (Ni), centered above each emitter tip (16). This technique employs image recognition algorithms to precisely locate the emitter tips (16) based on the divots created during the oxygen plasma back-etching step. The final step in the fabrication process is etching both the Al₂O₃ insulator layer (18) above each emitter tip (16) and the remaining resist around each tip using tetramethylammonium hydroxide (TMAH). This wet etching process selectively removes the Al₂O₃ and resist materials, leaving the silicon carbide emitter tip (16) exposed and creating the final device structure. The TMAH etch also undercuts the Al₂O₃ layer (18) beneath the nickel (Ni) electrode (20), optimizing the device geometry for low-voltage operation. The sequence of steps illustrated in FIG. 3, combining advanced lithographic and etching techniques with thin-film deposition methods, enables the fabrication of a silicon carbide based triode electron emitter (10) with precise control over nanoscale features and optimized performance characteristics. Each step in the process plays a critical role in achieving the desired device structure and ensuring efficient, low-voltage field emission. The figure details how the combination of FIB milling, resist planarization, oxygen plasma etching, thin film deposition, and TMAH etching enables the creation of the emitter structure, highlighting the invention's novelty in device design and fabrication methodology.

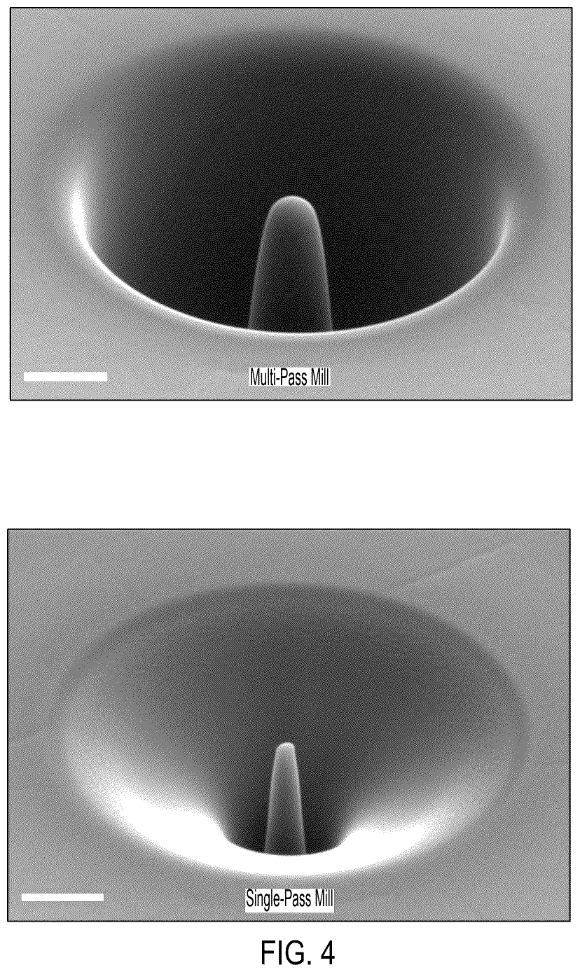

FIG. 4 provides a comparative illustration of silicon carbide emitter tips (16) fabricated using two different focused ion beam (FIB) milling approaches: the multi-pass approach and the single-pass approach employed in the fabrication of the silicon carbide based triode electron emitter (10). The figure presents scanning electron microscope (SEM) images of the emitter tips (16) fabricated using each method. FIG. 4(a) shows an emitter tip (16) created using the multi-pass FIB milling approach. In this method, the ion beam repeatedly scans a ring-shaped area, gradually milling the material to form the tip. This approach can result in a cylindrical well with vertical sidewalls around the emitter tip (16), creating a larger cavity that needs to be filled during the subsequent planarization process. The multiple passes also increase the risk of tip erosion and gallium contamination, which can degrade field emission performance. FIG. 4(b) depicts an emitter tip (16) fabricated using the single-pass FIB milling approach. In this method, the ion beam traverses the milling area only once, following a spiral pattern from the outer diameter to the inner diameter of the ring. This approach results in a tapered crater-like structure around the emitter tip (16), significantly reducing the cavity volume compared to the multi-pass method. The single-pass approach has several advantages. It reduces the milling time, minimizes gallium contamination and tip erosion, and creates a tapered cavity that simplifies the subsequent planarization process. The tapered profile of the cavity facilitates filling, resulting in a more uniform surface, which enhances the performance and reliability of the triode electron emitter (10). The reduced gallium contamination on the tip and reduced tip erosion preserve the electronic properties of the silicon carbide material at the apex (26) of the emitter tip (16), ensuring optimal field emission.

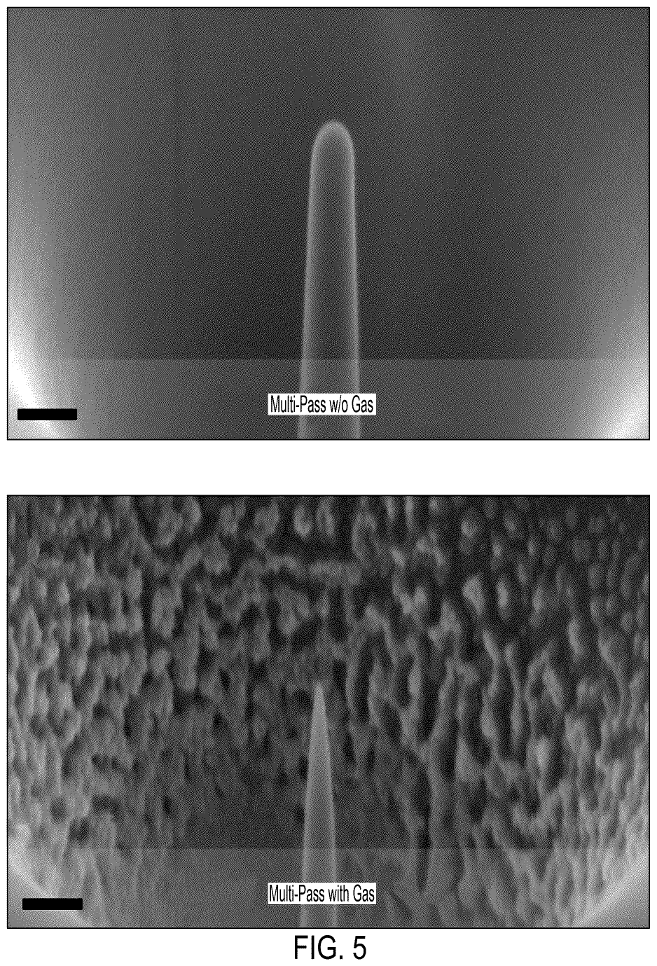

FIG. 5 shows the emitter tip (16) as an outcome of the sharpening process that can enhance the field emission properties of the silicon carbide based triode electron emitter (10). The figure shows scanning electron microscope (SEM) images of silicon carbide emitter tips (16) that were initially formed by single-pass FIB milling and then subjected to two different sharpening methods. FIG. 5(a) depicts an emitter tip (16) sharpened using multi-pass FIB milling without the use of any reactive gas. In this method, the ion beam repeatedly scans a ring-shaped area around the emitter tip (16), similar to the initial tip formation process, but with lower beam currents to minimize material removal. The resulting tip, while sharper than the initially formed tip, still has a radius of curvature greater than 20 nanometers, around 80 nm. This larger tip radius limits the field enhancement at the apex (26), involving higher voltages for electron emission. The multi-pass milling process without gas can also lead to some tip erosion and gallium contamination. FIG. 5(b) shows an emitter tip sharpened using multi-pass FIB milling in the presence of XeF₂ gas. This gas-assisted etching process significantly enhances the sharpening process, resulting in a much sharper tip with a radius of curvature less than 20 nanometers, typically below 10 nm. The XeF₂ gas reacts with the silicon carbide material in the presence of the gallium ion beam, which enhances the etching rate and produces a sharper tip. This chemical reaction is highly localized to the region where the ion beam strikes the material, allowing for fine control over the sharpening process, minimizing tip erosion, and preventing excessive material removal, which helps preserve the emitter tip's (16) structural integrity. The resulting sharp tip significantly amplifies the electric field at the apex (26), enabling efficient electron emission at lower voltages, which reduction in operating voltage is a key advantage of the silicon carbide-based triode electron emitter (10). The comparison between the tips sharpened with and without XeF₂ gas, as shown in FIG. 5, shows improvement in tip sharpness achieved through gas-assisted etching. This improved sharpness can provide low-voltage operation and enhanced field emission characteristics.

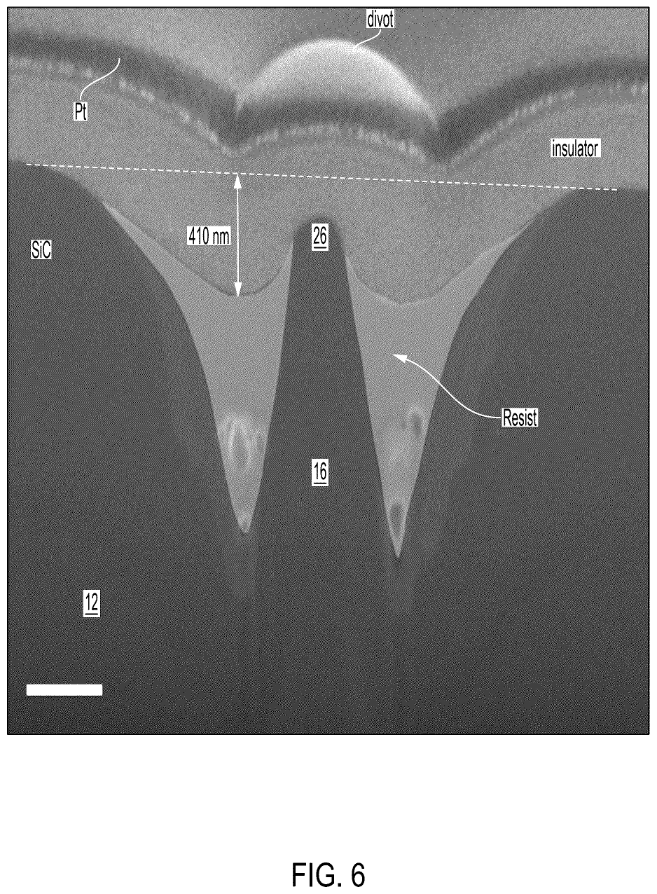

FIG. 6 provides a cross-sectional view of a silicon carbide emitter tip in its state of the process immediately before deposition of the metal extractor layer (16) and the surrounding trench after back-etching in the fabrication process for the silicon carbide based triode electron emitter (10). The figure shows a scanning electron microscope (SEM) image of a cross-section of the emitter tip (16) structure. The platinum (Pt) layer shown in the figure was added to assist in the FIB preparation of the cross section and is not part of the triode emitter structure. The silicon carbide substrate (12) is visible at the bottom of the image, forming the base for the emitter tip (16). The emitter tip (16) extends upward from the silicon carbide substrate (12). The emitter tip (16), formed by focused ion beam milling, has a conical shape to concentrate the electric field at its apex (26). The space between a portion of the tip (16) and substrate is coated with a LOR-3A photoresist to fill the surrounding concave section surrounding the emitter tip (16). The photoresist provides a surface topography around the emitter tip (16) filling the gaps or trenches created during the tip formation process. This is useful for creating a surface morphology for the subsequent deposition of the insulator layer (18) and extractor electrode (20). The LOR-3A coating is then back-etched using oxygen plasma, a process that selectively removes the photoresist material. The oxygen plasma etching creates a recess or divot over each emitter tip (16), which aids in aligning the extraction aperture (22) of the extractor electrode (20) with the emitter tip (16) during later fabrication steps. The depth of the recess is carefully controlled to achieve the desired geometry for optimal device performance. The formation of the divot from the emitter tip (16) is evident, highlighting a key advantage of this process—precise control over the device geometry at the nanoscale, which enables tailoring the emitter (10) characteristics for specific applications.

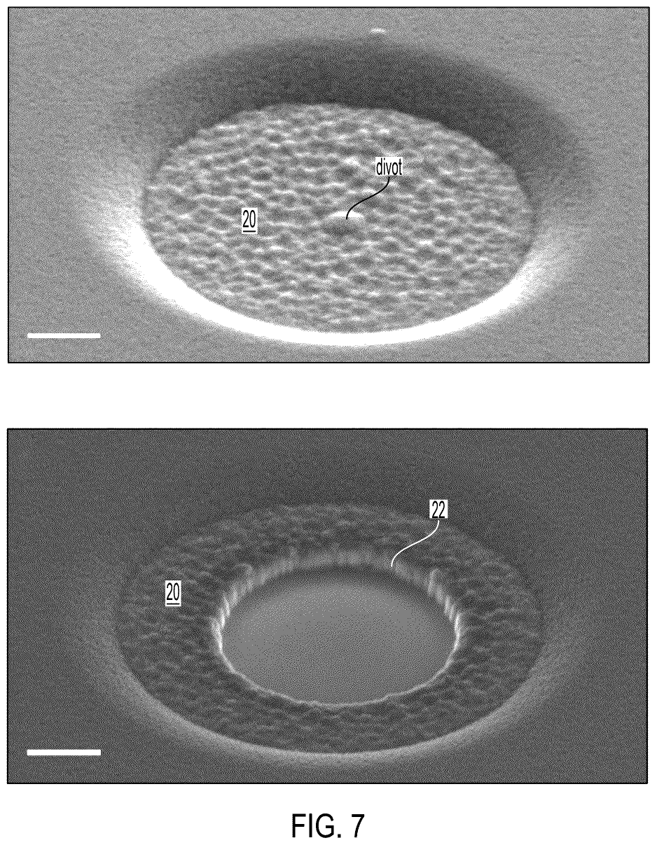

FIG. 7 shows aspects of the fabrication process of the silicon carbide based triode electron emitter (10) for the formation of the extraction aperture (22) in the extractor electrode (20). This aperture (22) plays a role in focusing the electric field at the emitter tip (16), maximizing electron extraction efficiency. The figure presents scanning electron microscope (SEM) images of the nickel (Ni) extractor electrode (20) before and after the aperture (22) formation, highlighting the precision achieved by the described method. FIG. 7(a) shows the nickel (Ni) film after deposition and planarization, with a distinct divot visible. This divot results from the recess created in the underlying photoresist during the oxygen plasma back-etching step, a process step in optimizing device performance and reliability, described earlier. The divot serves as a visual marker for the location of the buried emitter tip (16), aiding in the precise alignment of the extraction aperture (22) during subsequent FIB milling using gallium (as shown in FIG. 7) or another ion such as nitrogen, oxygen, argon or xenon. The nickel (Ni) film, forming the extractor electrode (20), provides a conductive path for the extracted electrons and shapes the electric field to optimize electron emission, and its smooth surface, achieved through sputtering deposition, minimizes electron scattering and secondary emission. The divot in the Ni film acts as a guide for the FIB milling process, ensuring accurate placement of the extraction aperture (22) over the buried emitter tip (16). FIG. 7(b) shows the nickel (Ni) film after FIB milling of the extraction aperture (22). The circular aperture (22), precisely centered within the divot, is created using a pattern recognition-based FIB milling process. This process employs image recognition algorithms to precisely locate the emitter tip (16) beneath the Ni film, based on detection of the circular depression and slightly protruding divot visible in the top surface of the Ni film. The circular shape of the aperture (22) focuses the electric field lines at the emitter tip (16) apex (26), enhancing field emission and shaping the emitted electron beam. The diameter of the extraction aperture (22), a parameter influencing device performance, is carefully controlled during the FIB milling process. A smaller diameter enhances field emission, allowing the silicon carbide based triode electron emitter (10) to operate at a lower voltage, while a larger diameter increases the emission current, which enhances the device performance by providing a higher current density. The precise centering of the aperture (22) within the divot ensures that the electric field is optimally focused onto the emitter tip's (16) apex (26), maximizing electron extraction efficiency and beam quality. The comparison of the Ni film before and after aperture (22) formation, depicted in FIG. 7, demonstrates the precision achieved by the described fabrication process. The use of pattern recognition-based FIB milling, guided by the detection of the circular depression and protruding divot in the Ni film, allows for accurate and repeatable placement of the extraction aperture (22), useful for device performance and reproducibility. This precision minimizes variations in device characteristics, ensuring consistent and reliable electron emission. The figure illustrates that combining advanced imaging techniques with FIB milling achieves precise control of nanoscale features. The image recognition-guided FIB milling approach, illustrated in FIG. 7, differentiates the fabrication process from conventional methods for forming extraction apertures, which methods may not offer the same level of precision and alignment accuracy on a tip by tip basis. The improved precision and alignment minimize variations in device characteristics and enhance device performance and provides a technical advantages. The figure's clear depiction of the circular aperture (22) precisely centered around the former location of the divot demonstrates the precision achievable by the fabrication process.

In an embodiment, a process for producing an electron beam with a silicon carbide based triode electron emitter 10 comprises: providing the silicon carbide based triode electron emitter (10) comprising a silicon carbide substrate (12) having a top surface (14), an emitter tip (16) formed integrally with and extending upward from the top surface (14) of the silicon carbide substrate (12), an insulator layer (18) on the top surface (14) of the silicon carbide substrate (12) and the emitter tip (16), and an extractor electrode (20) on the insulator layer (18), the extractor electrode (20) comprising an extraction aperture (22) centered over the emitter tip (16), and applying a voltage between the extractor electrode (20) and the silicon carbide substrate (12) to produce an electric field sufficient to extract electrons from the emitter tip (16) by field emission. In an embodiment, the emitter tip (16) has a radius of curvature less than 20 nanometers. In an embodiment, a lower surface (24) of the extractor electrode (20) is closer to an apex (26) of the emitter tip (16) than the top surface (14) of the silicon carbide substrate (12). In an embodiment, the insulator layer (18) has a thickness of less than 1 micrometer. In an embodiment, the silicon carbide substrate (12) is n-type silicon carbide. In an embodiment, the voltage is less than 100V. In an embodiment, the electric field at the apex (26) of the emitter tip (16) is at least 3 GV/m. In an embodiment, the emitter (10) is packaged in a vacuum environment. In an embodiment, the vacuum environment has a pressure of less than 10⁻⁶ Torr. In an embodiment, the process further comprises modulating the electron beam by optically biasing the silicon carbide substrate (12) with a blue or ultraviolet wavelength laser.

The process for producing an electron beam using a silicon carbide based triode electron emitter (10) leverages the unique properties of silicon carbide and the device's triode configuration to achieve efficient electron emission at reduced operating voltages. The process begins by providing a silicon carbide based triode electron emitter (10). This emitter (10) comprises a silicon carbide substrate (12) having a top surface (14), which serves as the base material and platform for subsequent fabrication. Silicon carbide, a wide-bandgap semiconductor, is chosen for its excellent thermal and electrical properties, for efficient and reliable field emission. The emitter tip (16) is formed integrally with and extends upward from the top surface (14) of the substrate (12), acting as the electron source. Its sharp geometry enhances the electric field, enabling electron emission at lower voltages. The insulator layer (18), deposited on the substrate (12) and emitter tip (16), electrically isolates the extractor electrode (20) from the substrate, and its predetermined thickness balances field enhancement and breakdown prevention. The extractor electrode (20), positioned on the insulator layer (18), incorporates an extraction aperture (22) centered over the emitter tip (16). This electrode (20) establishes the electric field for electron extraction, and the aperture (22) focuses this field onto the emitter tip (16), enhancing emission efficiency. The next step in the process involves applying a voltage between the extractor electrode (20) and the silicon carbide substrate (12). This applied voltage creates an electric field between the extractor electrode (20) and the emitter tip (16), of sufficient strength to extract electrons from the emitter tip (16) by field emission. Field emission, a quantum mechanical phenomenon, occurs when electrons tunnel through a potential barrier at the material's surface due to the applied electric field. The magnitude of the applied voltage determines the strength of the electric field, and thus the emission current. Lower operating voltages are desirable for simplifying device design and integration.

The emitter tip (16) can have a radius of curvature less than 20 nanometers, which enhances field emission by concentrating the electric field at the apex (26), reducing the voltage required for electron extraction. The lower surface (24) of the extractor electrode (20) being closer to the apex (26) of the emitter tip (16) than the top surface (14) of the silicon carbide substrate (12) maximizes the field enhancement effect while preserving electrical isolation, further reducing the operating voltage and minimizing breakdown. The insulator layer (18) can have a thickness of less than 1 micrometer, enhancing the electric field at the emitter tip (16) while providing sufficient electrical isolation. This thinner insulator layer enables lower voltage operation without compromising device reliability. The silicon carbide substrate (12) can be n-type silicon carbide, enhancing electron conductivity and thus improving field emission. The applied voltage can be less than 100V, significantly reducing power consumption and simplifying device integration compared to conventional cold field emitters that require kilovolt biases. This low voltage operation expands the application space for cold field emitters, enabling their use in portable and compact devices. The electric field at the apex (26) of the emitter tip (16) is at least 3 GV/m, a field strength sufficient for efficient field emission. Packaging the emitter (10) in a vacuum environment minimizes surface contamination and electron scattering, which can enhance the stability and longevity of the emitter and reduce performance degradation. The vacuum environment can have a pressure of less than 10⁻⁶ Torr, further minimizing contamination and improving the emitter's long-term stability and performance. Modulating the electron beam by optically biasing the silicon carbide substrate (12) with a blue or ultraviolet laser allows dynamic control over the emitted electron current. The energy of the laser, chosen to match or exceed silicon carbide's bandgap, maximizes optical absorption and modulation efficiency. This optical modulation technique enables high-speed control over the electron beam, expanding the range of applications to include high-speed electron microscopy and time-resolved electron diffraction studies.

The process of producing an electron beam begins with providing a silicon carbide based triode electron emitter (10). This emitter (10) is a miniaturized, low-voltage device designed for efficient electron emission. The emitter (10) comprises a silicon carbide substrate (12) which serves as the base material. Silicon carbide's excellent thermal and electrical properties make it an ideal choice for field emission applications. The substrate (12) can be a single-crystal wafer, providing a uniform, high-quality platform for device fabrication. Atop the substrate (12) is a top surface (14), which acts as the interface for the subsequent layers. The emitter tip (16) is formed integrally with and extends upward from this top surface (14). The emitter tip (16) is the heart of the electron source; its sharp geometry, with a radius of curvature less than 20 nanometers, amplifies the electric field, which allows efficient electron emission at reduced voltages. This integral formation of the emitter tip (16) with the silicon carbide substrate (12) creates a robust structure, minimizing issues like delamination or material mismatch that can occur with deposited emitter tips. The emitter (10) also incorporates an insulator layer (18). This layer is deposited on the top surface (14) of the silicon carbide substrate (12) and the emitter tip (16). Its function is twofold: it electrically isolates the extractor electrode (20) from the substrate (12) and enhances the electric field at the emitter tip (16). The insulator layer's (18) thickness is a carefully chosen parameter. A thinner layer maximizes field enhancement but also increases the risk of electrical breakdown. The predetermined thickness of the insulator layer (18) balances these factors for optimum device performance and reliability. The extractor electrode (20), a element of the triode configuration, is formed on the insulator layer (18). It incorporates an extraction aperture (22) centered precisely over the emitter tip (16), which focuses the electric field onto the tip, maximizing electron extraction. The extractor electrode (20) and the extraction aperture (22) play critical roles in modulating and shaping the emitted electron beam. While silicon carbide is the preferred material for the substrate (12) due to its exceptional thermal and electrical properties, alternatives like aluminum nitride or diamond can be considered depending on the specific application requirements. Variations in the emitter tip (16) geometry, insulator (18) material and thickness, and extractor electrode (20) design, including the shape and size of the extraction aperture (22), are possible and provide flexibility for customizing the electron emission characteristics to meet specific application needs. The ability to tailor the emitter design and materials underscores the versatility of this silicon carbide-based triode electron emitter (10) compared to conventional electron sources.

Having provided the silicon carbide based triode electron emitter (10), the next step in producing an electron beam is applying a voltage between the extractor electrode (20) and the silicon carbide substrate (12). This applied voltage creates the electric field necessary for electron extraction from the emitter tip (16). The magnitude of the applied voltage is a parameter that determines the strength of the electric field, and consequently, the emission current. Due to the field enhancement effect of the emitter tip (16) and the triode configuration, the required voltage for electron extraction is significantly lower compared to conventional cold field emitters, typically less than 100V. This lower operating voltage simplifies device design, reduces power consumption, and enables the use of simpler, more compact power supplies. The applied voltage generates an electric field between the extractor electrode (20) and the silicon carbide substrate (12). This electric field is concentrated at the apex (26) of the emitter tip (16) due to its sharp radius of curvature (less than 20 nanometers). The concentrated electric field at the apex (26) must be of sufficient strength to extract electrons from the emitter tip (16) by field emission. Field emission is a quantum mechanical process where electrons tunnel through a potential barrier at the material's surface due to the applied electric field. The electric field strength required for field emission typically exceeds several GV/m. The applied voltage, the geometry of the emitter (10), and the material properties of the silicon carbide determine the electric field strength at the apex (26) of the emitter tip (16). The closer proximity of the extractor electrode's (20) lower surface (24) to the emitter tip (16) apex (26) compared to the top surface (14) of the silicon carbide substrate (12) enhances this field, thus reducing the required applied voltage. The applied voltage can be DC or pulsed, with variations in the voltage waveform enabling modulation of the emitted electron beam's intensity or temporal characteristics. For example, pulsed voltages can generate short bursts or pulses of electrons, useful in time-resolved experiments. The specific voltage applied, its waveform, and the resulting electric field strength at the emitter tip (16) apex (26) are relevant parameters related to the operation of the emitter.

In an embodiment of the process for producing an electron beam, the electric field at the apex (26) of the emitter tip (16) of the silicon carbide based triode electron emitter (10) is at least 3 GV/m. This high electric field strength is for enabling field emission, the quantum mechanical process by which electrons are extracted from the emitter tip (16). When a voltage is applied between the extractor electrode (20) and the silicon carbide substrate (12), an electric field is generated between the extractor electrode (20) and the emitter tip (16). Due to the emitter tip's (16) sharp geometry, with a radius of curvature less than 20 nanometers, the electric field lines converge and concentrate at the apex (26) of the tip (16), resulting in a substantial field enhancement. An electric field strength of at least 3 GV/m is generally sufficient to induce substantial electron emission from the emitter tip's (16) apex (26) via field emission. The strength of the electric field at the apex (26) depends on the applied voltage, the distance between the extractor electrode (20) and the emitter tip (16), and the tip's (16) geometry including its radius of curvature and height. A sharper tip with a smaller radius of curvature results in a higher field enhancement for a given applied voltage. The closer proximity of the extractor electrode's (20) lower surface (24) to the emitter tip's (16) apex (26), compared to the substrate's top surface (14), further amplifies the electric field strength at the apex (26), promoting field emission at lower voltages. The electric field strength at the apex (26) can be calculated using finite element analysis or other numerical simulation methods. These simulations take into account the geometry of the emitter (10), including the shape and dimensions of the emitter tip (16), insulator layer (18), and extractor electrode (20), as well as the applied voltage and material properties such as the dielectric constant of the insulator.

An aspect of the process for using the silicon carbide based triode electron emitter (10) involves packaging the emitter in a vacuum environment. This vacuum environment is useful for preventing electron scattering, minimizing surface contamination, and ensuring stable and reliable field emission. When operating the emitter (10), applying a voltage between the extractor electrode (20) and the silicon carbide substrate (12) extracts electrons from the emitter tip (16) by field emission. These emitted electrons form an electron beam, the characteristics of which, including its current, energy, and coherence, are critical for many applications. The vacuum environment minimizes interactions between the emitted electrons and residual gas molecules, preventing scattering of the electrons and ensuring the formation of a well-defined, focused electron beam. The vacuum environment also minimizes surface contamination of the emitter tip (16), as residual gas molecules can adsorb onto the tip surface, altering its work function and degrading field emission performance over time. By operating in a vacuum, the emitter tip (16) remains clean, ensuring stable and long-term device operation. The vacuum environment can be achieved by enclosing the emitter (10) in a sealed package or chamber and evacuating the air or other gases to a low pressure, typically below 10⁻⁶ Torr. This low pressure is sufficient to minimize electron scattering and surface contamination. The vacuum can be maintained using various pumping technologies, like ion pumps, turbomolecular pumps, or cryopumps, each with advantages and disadvantages regarding attainable pressure, pumping speed, and maintenance requirements. The choice of vacuum pump will depend on the specific application and the desired vacuum level. Variations in vacuum levels can be used to optimize device performance and lifetime. Higher vacuum levels reduce scattering and contamination effects.

In an embodiment of the process for producing an electron beam using the silicon carbide based triode electron emitter (10), the vacuum environment in which the emitter is packaged has a pressure of less than 10⁻⁶ Torr. This low pressure is critical for minimizing electron scattering, reducing surface contamination, and maintaining stable field emission. When the emitter (10) is operated in a vacuum, the emitted electrons can travel from the emitter tip (16) to the extraction aperture (22) with minimal scattering by residual gas molecules. At pressures less than 10⁻⁶ Torr, the mean free path of the electrons is significantly longer than the distance between the emitter tip (16) and the extraction aperture (22), minimizing the probability of collisions between the electrons and residual gas molecules. This reduced scattering preserves the electron beam's coherence and directionality, which is for applications such as electron microscopy or lithography. Maintaining a low pressure also reduces the rate of surface contamination of the emitter tip (16). Residual gas molecules can adsorb onto the emitter tip (16) surface, altering its work function and degrading field emission performance over time. At pressures less than 10⁻⁶ Torr, the flux of residual gas molecules impinging on the emitter tip (16) is significantly reduced, minimizing contamination and preserving long-term device stability and performance. The specific vacuum level required for optimal operation depends on factors like the emitter (10) geometry, the applied voltage, and the specific application requirements. While a pressure of less than 10⁻⁶ Torr is sufficient for stable field emission, even lower pressures can be beneficial for certain applications, especially those requiring extremely high beam coherence or long device lifetimes. Higher vacuum levels generally enhance device performance and longevity, but may require more complex and expensive vacuum pumping systems.

A further embodiment of the process for producing an electron beam with the silicon carbide based triode electron emitter (10) involves modulating the electron beam by optically biasing the silicon carbide substrate (12) with a blue-wavelength laser. This optical biasing technique allows dynamic control over the electron emission, enabling applications requiring modulated electron beams, such as high-speed electron microscopy or time-resolved electron diffraction. When a blue laser illuminates the silicon carbide substrate (12), the incident photons generate electron-hole pairs in the silicon carbide material. This alters the local conductivity and, consequently, the electric field distribution near the emitter tip (16). This change in the electric field modulates the electron emission current, providing a mechanism for controlling the intensity of the emitted electron beam. The blue laser wavelength, typically in the range of 400-480 nm, is selected to match or exceed the bandgap of silicon carbide, enhancing optical absorption in the substrate (12) and maximizing the modulation effect. The intensity of the blue laser can be modulated to vary the electron beam current, allowing for precise control over the beam's intensity. The modulation frequency of the laser can also be varied to control the temporal characteristics of the electron beam, which enables high-speed modulation. Alternative light sources, like ultraviolet (UV) lasers or LEDs, can be considered for optical biasing, though their effectiveness may differ depending on their wavelength and intensity. The choice of light source depends on the silicon carbide material's bandgap and the specific modulation requirements of the application. While optical biasing offers advantages in terms of speed and controllability, other methods of modulating the electron beam are possible, including electrical modulation by varying the applied voltage between the extractor electrode (20) and the substrate (12), or magnetic modulation using a magnetic field. However, optical biasing provides a non-contact method for modulating the electron beam, simplifying device design and integration, as it does not require additional electrodes or magnetic components near the emitter tip (16). In this optical biasing technique, properties such as the wavelength and intensity of the blue laser, the modulation frequency, and the method of coupling the laser light to the silicon carbide substrate (12) provide control over characteristics of the modulated electron beam, such as its current, energy, and temporal profile.

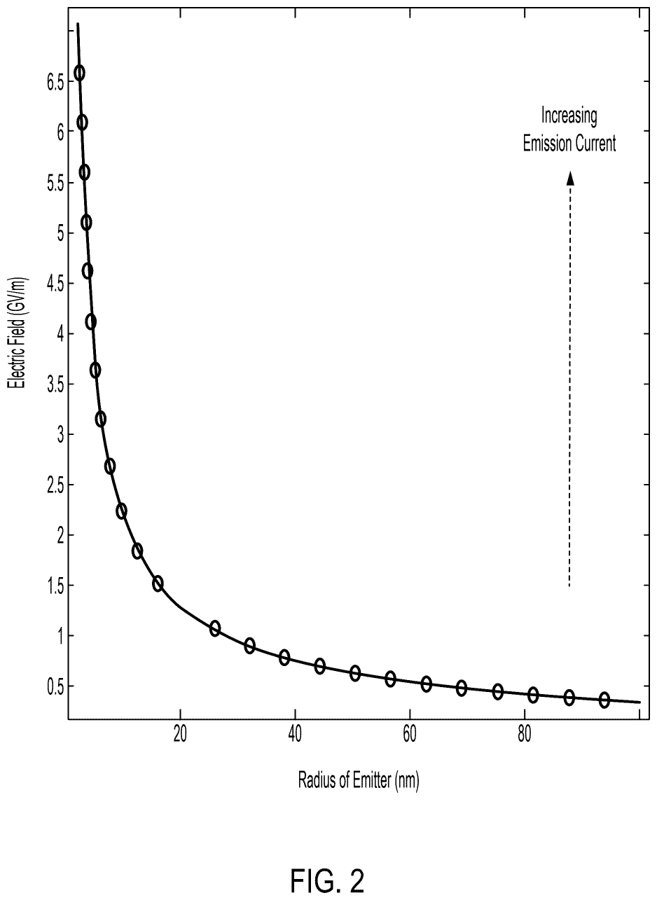

FIG. 2 illustrates the relationship between the electric field at the apex (26) of the emitter tip (16) and the emitter tip radius, a factor influencing the performance of the silicon carbide based triode electron emitter (10). The figure presents a simulation result obtained using a finite element electrostatic solver, demonstrating how the electric field strength at the apex (26) of the emitter tip (16) varies with the tip radius. A 50V bias is applied between the emitter tip (16) and an extractor electrode (20) positioned 200 nm above the tip. The extractor electrode (20) has an aperture (22) with a diameter of 300 nm, centered on the emitter tip (16). The simulation results demonstrate that as the emitter tip (16) radius decreases, the electric field at the apex (26) increases significantly. This field enhancement effect is a principle underlying the operation of field emission devices. Sharper tips, with smaller radii of curvature, concentrate the electric field lines more effectively, leading to higher field strengths at the apex (26), and thus facilitating electron emission at lower voltages. For emitter tip (16) radii below approximately 20 nm, the electric field at the apex (26) increases dramatically, reaching values exceeding 3 GV/m, which high field strength is sufficient for initiating substantial field emission. This sharp increase in electric field strength at smaller tip radii highlights the importance of precise control over the emitter tip (16) geometry during the fabrication process. Techniques like focused ion beam milling, especially with gas-assisted etching, can achieve the required nanoscale precision for creating sharp emitter tips with radii below 20 nm. The figure demonstrates the direct relationship between the emitter tip (16) radius and the resultant electric field strength at the apex (26). This relationship is a consequence of the geometry of the emitter tip and its influence on the electric field distribution. Sharper tips concentrate the electric field lines more effectively, leading to higher field enhancement and lower operating voltages for field emission. The simulation results presented in the figure provide valuable guidance for designing and optimizing the emitter tip (16) geometry to achieve the desired electric field strength and emission characteristics. For example, by tailoring the emitter tip (16) radius through precise fabrication methods, it's possible to achieve a target electric field strength at a specific operating voltage. This enables customization of the emitter (10) for various applications, balancing performance requirements with practical considerations like device size and power consumption. The choice of materials, particularly for the insulator layer (18) and the extractor electrode (20), also influences the electric field distribution. Higher dielectric constant materials for the insulator (18) enhance the field at the emitter tip (16), and materials with different work functions for the extractor electrode (20) can modify the field emission properties. The simulation results presented in FIG. 2 highlight the strong dependence of the electric field strength on the emitter tip (16) radius and underscores the importance of precise control over nanoscale geometry for achieving optimal field emission performance. This understanding of the relationship between tip radius and electric field strength is useful for optimizing device performance and achieving efficient, low-voltage operation of silicon carbide based triode electron emitters.

Conventional cold field emitters, often relying on sharp metallic tips, typically require high voltages for electron emission, posing challenges for device integration and power management. Field emitter arrays, while offering lower operating voltages, suffer from limitations in current density and lifetime due to tip degradation. Furthermore, conventional fabrication processes can be complex, hindering scalability and cost-effectiveness. The silicon carbide based triode electron emitter (10) distinguishes itself through a combination of material selection, device architecture, and fabrication methods. The use of silicon carbide as the substrate material leverages its unique thermal and electrical properties, enabling efficient heat dissipation and contributing to enhanced device longevity. The emitter tip (16), integrally formed with the silicon carbide substrate (12) and sharpened to a radius of curvature less than 20 nanometers, enhances field emission at significantly reduced voltages compared to conventional emitters requiring kilovolt biases. This monolithic construction also eliminates potential failure points like delamination common in some field emitter arrays. The triode configuration, incorporating an insulator layer (18) with a predetermined thickness and an extractor electrode (20) with a precisely aligned extraction aperture (22), further reduces the operating voltage and enhances device reliability. The fabrication process, using focused ion beam milling, gas-assisted etching, and planarization techniques, achieves a level of precision and control over nanoscale geometry not readily achievable with conventional fabrication methods. The disclosed emitter distinguishes itself from prior art by addressing the limitations of conventional cold field emitters. Its lower operating voltage, enabled by the sharp emitter tip (16) and the triode configuration, simplifies device integration and power management. The use of silicon carbide as the substrate material (12) improves heat dissipation and extends operational lifetime. The robust, monolithic emitter tip (16) construction enhances device reliability and reduces tip degradation. The fabrication process, using advanced lithographic techniques, enables reproducible manufacturing of emitters with precise control over nanoscale geometry, further enhancing device performance and consistency. These combined features provide the emitter operating at a low-voltage, with high-performance as a reliable electron source for a wide range of applications.

Advantageously, the silicon carbide based triode electron emitter 10 can be made in field emitter arrays (FEAs), arrays of thousands to millions of individual microscale to nanoscale cold field emitters, providing a scaling of the emission current compared to that obtained from conventional single tip field emitter. By placing the extraction electrode closer to the plane of tips with ~nm scale radii, relatively low operation voltages (100 to 300 V) can be achieved. In turn, the low voltage of operation of these cathodes made them less vulnerable to damage by ionization of the ambient gas, thus enabling operation at relatively low vacuum.

In the SiC based electron cold field emitter in a triode configuration, SiC provides several benefits such as a high thermal conductivity (enabling efficient heat dissipation), high electron mobility (enabling reduced scattering of electrons, thus lower resistive heating), high hardness (enabling reduced deuteriation due to reverse ion bombardment) and enhanced electron affinity (enabling enhanced emission current densities). Furthermore, focused ion beam milling used to fabricate the emitter tip arrays in SiC is relatively substrate agnostic and can be extended to form emitter tip arrays of other materials of interest to cold field emission, such as AlN, ZnO, and GaN. Since SiC is amongst the hardest known materials, moving to other materials would not be expected to lead to an increase in array patterning time.

The silicon carbide based triode electron emitter 10 provides a high current density of electrons and is compact with sub-100V operating voltages that can be used as a cold field emitter in diverse applications such as handheld X-ray imaging machines used in hospitals or mobile nursing units and miniaturized X-Ray sources for computed tomography as well as in applications ranging from microwave amplifiers for space based communications, to security to semiconductor analysis.

The articles and processes herein are illustrated further by the following Example, which is non-limiting.

### Example

A solid state, triode geometry-based field emitter array includes conductive SiC nanotips, all monolithically formed from a SiC wafer, and each having its own integrated metallic extraction aperture, positioned at a controlled, typically submicron scale distance. The refractory nature of SiC coupled with its good thermal conductivity (130 Wm⁻¹K₋₁) leads to resilient emitters, capable of withstanding high current densities, and capable of efficient heat dissipation. Furthermore, the wide band gap of the material along with the possibility of relatively high doping levels (typically n-type) enhances electron affinity and leads to increased emission.

The SiC-based emitter arrays is made with high control of tip shape and sharpness, as well as an efficient, virtually substrate agnostic approach to shaping a material like SiC that is challenging to etch using conventional techniques such as reactive ion etching. Here, focused ion beam (FIB) milling is used. The combination of a high FIB current and efficient ring-shaped single-pass milling strategy enables to the realization of large arrays of tips having a reproducibly uniform conical shape, in a reasonable, potentially commercially viable process time. A second, XeF₂ gas-assisted, ring-shaped multipass milling step at lower FIB currents enables sharpening of the tip of each SiC cone to a sub-10 nm tip diameter with minimal reduction of tip height. This is followed by a pseudo-planarization process that forms an integrated extraction plane consisting of a thin film of refractory metal (such as Cr or Ni) isolated from the top surface of SiC substrate by a high-breakdown voltage insulator layer (such as Al₂O₃), in which metallic apertures individually centered on each tip are formed by FIB milling followed by wet chemical removal, through the apertures of the remaining planarization material around each tip. The height of the plane of the metallic extraction aperture above each tip is controlled by the back-etch step of the planarization process and can be reduced below the thickness of the insulator layer. This brings the plane of extractor apertures closer to each tip, minimizing that required extraction voltages, while simultaneously maintaining the breakdown voltage of the insulator at its initial, significantly higher value.

Cold field emission occurs through a quantum mechanical tunneling process. When a strong electric field is applied to a sharp-pointed or finely structured cathode, it creates a potential barrier for electrons to overcome. According to the Fowler-Nordheim (FN) equation, the emission current density (J) depends exponentially on the applied electric field (E) and the work function (φ) of the material according to:

$$J = \frac{A {β}^{2} {E}^{2}}{ϕ} exp ( - \frac{B {ϕ}^{1.5}}{β E} )$$

where A and B are constants dependent on the properties of the material. The FN equation indicates that higher electric fields, higher E-Field enhancement and lower work functions facilitate a higher emission current density.

The device structure shown in FIG. 1, by positioning the plane of the extraction electrode (e.g. of the extraction aperture) close to the tip (cathode), has higher extraction electric fields for a given applied voltage between extractor and substrate. Furthermore, a sharp tip fabricated out of a highly doped n-type SiC wafer ensures a large electric field enhancement as the tip radius is reduced (FIG. 2), as simulated using a finite element solver. A sharp increase in field is obtained for emitter radii ~20 nm and below. For example, upon application of a 50V bias across a 200 nm thick oxide, a bare SiC wafer would experience an electric field of 0.25 GV/m at its surface, whereas a SiC tip with a radius of curvature of ~10 nm, biased at the same voltage across the same distance in air, experiences a field at its apex of >3 GV/m, which is a 12× enhancement. SiC has a low work function (~4 eV) for lower turn-on voltage, and high emission currents at a given voltage.

### Fabrication Process

Making the array can occur as shown in FIG. 3, wherein a 1 cm by 1 cm square piece of n-type SiC wafer is subjected to automated, high-current, ring-shaped, single pass FIB milling to form an array of emitters that is milled into the substrate. This SiC cone formation step is followed by an automated sharpening step using an automated low-current, ring shaped, XeF₂ gas-assisted FIB milling strategy, where image recognition is used to center the sharpening mill pattern on each tip. This is followed by a planarization step consisting of spin coating two to three layers of LOR-3A resist. After each spin coating step, the sample is baked at a temperature higher than the glass transition temperature of the resist (>250° C.). This induces resist reflow which enhances the planarization of the trenches. The resist is then back etched in an O₂ plasma. Due to electric field concentration on the tips during this process, the area around each tip experiences a higher etch rate, resulting in divots. An Al₂O₃ spacer layer and an Ni extractor metal layer are then sequentially deposited via sputtering. Circular apertures through the Ni film, centered above each tip, are fabricated by automated FIB milling, using image recognition of the divots to center milled apertures on the tip positions. Thereafter, the samples is dipped in 5% TMAH solution at an elevated temperature. This etches away in the same step both the Al₂O₃ above the tips (with some lateral etching as well under the Ni) and the residual resist coating the tips, which can occur at the same time, under etching Al₂O₃.

Various steps in making the emitter array are described here.

### Step 1a: Single-Pass Milling.

A FIB mill process to form a tip, which includes a multi-pass scan over a ring-shaped area, results in an etched cylindrical well with vertical sidewalls (FIG. 4a), which, for a given tip height, results in a maximal volume which proves challenging to fill during planarization. The multiple passes to which the tip is exposed through beam tails also leads to excess tip erosion and Ga contamination of the tip. Alternatively, one can use a single-pass FIB milling strategy, in which the beam progresses just once, in a single spiral pattern, from the outer diameter to the inner diameter of the ring. This leads to a significantly faster mill time due to the angle of the beam at each moment with respect to the milled surface (here, glancing incidence versus normal incidence in the conventional case; lower exposure of the tip under formation to erosion and Ga contamination; and backfilling of the cavity by redeposited FIB sputtered material (FIG. 4b), forming a tapered crater that reduces the cavity volume necessary to fill during the planarization process.

### Step 1b: Gas-Assisted Tip Sharpening.

To reduce the extractor voltage needed for emission, each tip is further sharpened using a novel gas-assisted sharpening strategy. By exposing a pre-milled SiC tip to a partial pressure of XeF₂ during a second multi-pass, ring-shaped, FIB mill at low beam current, significant tip sharpening can be achieved, reducing the radius of curvature at the tip. This sharpening of the tips occurs because the edges and sidewalls of the tip experience a higher etch than the flat top under reactive gas exposure (FIG. 5). Whereas milling without gas was found to produce tips of diameter no smaller than ~80 nm, a tip diameter of less than 10 nm could be achieved when XeF₂ gas was used.

### Step 2: Planarization Using Resist Reflow of Resist.

Trenches of maximum depth of over 1 μm, even when partially filled to an inverse conical shape with FIB redeposited SiC, proved to be challenging to adequately planarize in a single step of spin coating step of resist or spin-on oxide. Here, we achieve planarization of the tapered trenches by stacking multiple (two to three) coats of LOR-3A, where a final thickness of ~300 nm is achieved for each layer. Each individual coat is achieved by a spin coating followed by 2 critical process steps. First, the sample is left in the spin coater for ~5 minutes after spinning. Spinning resist on the relatively small (1 cm by 1 cm) SiC substrate we use leads to formation of resist edge beads, which contribute to reverse resist flow towards the center and assist in planarization of the sample while the resist is still unbaked. Second, the resist-coated sample is heated to a temperature higher than the glass transition temperature of the resist (>250° C.), enabling reflow. A slow temperature ramp up to 250° C. and back down to room temperature is used for this step. By depositing two such coats for example over a tip bearing tapered trench array of maximum depth ~1 μm, full filling and planarization of each trench was achieved, with a planar resist overcoat having thickness 700 nm above the top plane of the SiC wafer. Three coats yield a corresponding thickness of 980 nm.

### Step 3: Back Etching Using O2 Plasma.

To remove the resist everywhere on the flat SiC surface while preserving resist overcoating of tips within the trenches, the LOR-3A coating is partially back etched in an O₂ plasma. Electric-field enhancement at the tips result in a higher etch rate in their vicinity. This results in a pseudo-planarized surface (FIG. 6). There are multiple benefits of this pseudo-planarization. As subsequent insulator and extraction electrode layers of Al₂O₃ and Ni are deposited, the divot corresponding to the resist depression in the trench is maintained. This results in distance from the lower plane of the Ni layer to the SiC tip that is smaller than to SiC surface through the oxide. This enables the emitters to turn on at lower voltage and reduces incidence of breakdown of the oxide. Second, the divot can be seen under an optical and ion beam microscope. Bringing the plane of extractor apertures closer to each tip, minimizes the required extraction voltage, while simultaneously maintaining the breakdown voltage of the insulator at a significantly higher value.

### Step 6: Ni Milling Using Pattern Recognition.

The presence of trench divots that are visible in a FIB image enables implementation of an automated FIB milling process to form the circular apertures in the Ni film (FIG. 7). Image recognition is used to accurately and individually center aperture mills on position of each buried tip, itself centered to the divot. FIG. 7a displays a SEM image of a divot as it appears after deposition of both Al₂O₃ and Ni layers. FIG. 7b shows the result of FIB milling a circular aperture in the center of the divot, where the centering is achieved using automatic image recognition to place the mill. The aperture is milled with a dose such that it fully penetrates through the Ni but stops on the Al₂O₃ layer. The sequential direct-write FIB process enables apertures of arbitrary shape and size, which can be locally tailored to tune the emission properties of individual tips, depending on global the requirements of the array such as beam shaping or point.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

### PARTS LIST

silicon carbide based triode electron emitter 10
silicon carbide substrate 12
top surface 14
emitter tip 16
insulator layer 18
extractor electrode 20
extraction aperture 22
lower surface 24
apex 26

What is claimed is:

1. A silicon carbide based triode electron emitter (10) comprising: a silicon carbide substrate (12) having a top surface (14); an emitter tip (16) formed integrally with and extending upward from the top surface (14) of the silicon carbide substrate (12), the emitter tip (16) having a radius of curvature less than 20 nanometers; an insulator layer (18) on the top surface (14) of the silicon carbide substrate (12) and the emitter tip (16), the insulator layer (18) having a predetermined thickness; an extractor electrode (20) on the insulator layer (18), the extractor electrode (20) comprising an extraction aperture (22) centered over the emitter tip (16); wherein a lower surface (24) of the extractor electrode (20) is closer to an apex (26) of the emitter tip (16) than the top surface (14) of the silicon carbide substrate (12).

2. The silicon carbide based triode electron emitter of claim 1, wherein the emitter tip (16) is conical.

3. The silicon carbide based triode electron emitter of claim 1, wherein the emitter tip (16) has a height of at least 0.5 micrometers.

4. The silicon carbide based triode electron emitter of claim 1, wherein the insulator layer (18) has a thickness of less than 1 micrometer.

5. The silicon carbide based triode electron emitter of claim 1, wherein the insulator layer (18) is aluminum oxide.

6. The silicon carbide based triode electron emitter of claim 1, wherein the extractor electrode (20) is nickel.

7. The silicon carbide based triode electron emitter of claim 1, wherein the extraction aperture (22) is circular.

8. The silicon carbide based triode electron emitter of claim 1, wherein the extraction aperture (22) has a diameter from 100 nanometers to 500 nanometers.

9. The silicon carbide based triode electron emitter of claim 1, wherein the silicon carbide substrate (12) is n-type silicon carbide.

10. The silicon carbide based triode electron emitter of claim 1, wherein the silicon carbide substrate (12) has a thickness of at least 50 micrometers.

11. A process for fabricating a silicon carbide based triode electron emitter (10), the process comprising:
providing a silicon carbide substrate (12) comprising a top surface (14);
forming an emitter tip (16) integrally with and extending upward from the top surface (14) of the silicon carbide substrate (12), the emitter tip (16) having a radius of curvature less than 20 nanometers;
depositing an insulator layer (18) on the top surface (14) of the silicon carbide substrate (12) and the emitter tip (16), the insulator layer (18) comprising a predetermined thickness; and
forming an extractor electrode (20) on the insulator layer (18), the extractor electrode (20) comprising an extraction aperture (22) centered over the emitter tip (16), wherein a lower surface (24) of the extractor electrode (20) is closer to an apex (26) of the emitter tip (16) than the top surface (14) of the silicon carbide substrate (12).

12. The process of claim 11, wherein forming the emitter tip (16) comprises focused ion beam milling.

13. The process of claim 12, wherein the focused ion beam milling comprises single-pass milling.

14. The process of claim 11, wherein the emitter tip (16) is formed with a conical shape.

15. The process of claim 11, further comprising sharpening the emitter tip (16) by focused ion beam milling in the presence of XeF₂ gas.

16. A process for producing an electron beam with a silicon carbide based triode electron emitter 10, the process comprising:
providing a silicon carbide based triode electron emitter (10) comprising: a silicon carbide substrate (12) comprising a top surface (14); an emitter tip (16) formed integrally with and extending upward from the top surface (14) of the silicon carbide substrate (12); an insulator layer (18) on the top surface (14) of the silicon carbide substrate (12) and the emitter tip (16); and an extractor electrode (20) on the insulator layer (18), the extractor electrode (20) comprising an extraction aperture (22) centered over the emitter tip (16); and
applying a voltage between the extractor electrode (20) and the silicon carbide substrate (12) to produce an electric field sufficient to extract electrons from the emitter tip (16) by field emission.

17. The process of claim 16, wherein the emitter tip (16) comprising a radius of curvature less than 20 nanometers and greater than 1 nm.

18. The process of claim 16, wherein a lower surface (24) of the extractor electrode (20) is closer to an apex (26) of the emitter tip (16) than the top surface (14) of the silicon carbide substrate (12).

19. The process of claim 16, wherein the insulator layer (18) comprises a thickness of less than 1 micrometer and greater than 100 nm.

20. The process of claim 16, further comprising modulating the electron beam by optically biasing the silicon carbide substrate (12) with a blue laser.
